(19) United States
(12) Patent Application Publication
(10) Pub. No.: US 2012/0287959 A1
(43) Pub. Date: Nov. 15, 2012

(54) GERMANIUM LIGHT-EMITTING ELEMENT

(76) Inventors: Kazuki Tani, Kokubunji (JP); Shinichi Saito, Kawasaki (JP); Toshiki Sugawara, Kokubunji (JP); Youngkun Lee, Hachioji (JP); Digh Hisamoto, Kokubunji (JP); Makoto Miura, Tsukuba (JP); Katsuya Oda, Hachioji (JP)

(21) Appl. No.: 13/521,533

(22) PCT Filed: Jan. 28, 2011
(86) PCT No.: PCT/JP2011/051806

§ 371 Date: Jul. 11, 2012

(30) Foreign Application Priority Data
Mar. 8, 2010 (JP) 2010-050597

(51) Int. Cl. H01S 5/22

(52) U.S. Cl. 372/45.01

(57) ABSTRACT

A germanium light-emitting device emitting light at high efficiency is provided by using germanium of small threading dislocation density. A germanium laser diode having a high quality germanium light-emitting layer is attained by using germanium formed over silicon dioxide. A germanium laser diode having a carrier density higher than the carrier density limit that can be injected by existent n-type germanium can be provided using silicon as an n-type electrode.

### TECHNICAL FIELD

The present invention concerns a light-emitting element using germanium and it particularly relates to a germanium laser diode and a manufacturing method thereof.

### BACKGROUND ART

In broad band networks supporting internet industries, optical communication has been adopted. For light transmission and reception in the optical communication, laser diodes using compound semiconductors belonging to group III-V, or group II-VI, etc. are used.

On the other hand, information processing and storage are performed on silicon-based LSI and transmission of information is performed by a laser based on compound semiconductors. The field of study intending to attain short distance optical interconnection such as inter-chip or intra-chip of silicon by an optical element using silicon is referred to as silicon photonics. This is a technique intending to prepare an optical element by using refined silicon lines that have been generally popularized worldwide. At present, while LSI (abbreviation of Large Scale Integration, Large Scale Integrated Circuit) based on CMOS (Complementary Metal-Oxide-Semiconductor: Complementary MOS transistor) have been produced in such silicon lines, it is considered that fused circuit technique of photonics and electronics of integrating an optical circuit by such silicon photonics with CMOS circuit will be realized in the future.

The most challenging subject in the silicon photonics is a light source. This is because emission efficiency is extremely poor in silicon or germanium in a bulk state, since they are indirected transition semiconductors.

Then, a method of changing silicon and germanium into direct transition semiconductor in order for light emission of them at high efficiency has been proposed.

One of method of changing germanium to a direct transition semiconductor, a method of application of tensile strain has been known. When tensile strain is applied to germanium, the energy at the r valley at the conduction band decreases depending on the magnitude of the strain. As a result of applying tensile strain, if the energy at the Γ valley is smaller than the energy at the L valley, germanium changes into a direct transition type semiconductor.

In the Non-Patent Literature 1, it is reported that germanium is changed into a direct transition semiconductor by applying tensile strain at about 2 GPa. Further, as a preparation method, Patent Literature 2 (JP-T No. 2005-530360) discloses a method of epitaxial growth of germanium directly on silicon and applying tensile strain to germanium by utilizing the difference of thermal expansion coefficient between silicon and germanium. Further, since the energy gap is as small as 0.136 eV between the L valley at the bottom of the conduction band of germanium and at the Γ valley at the energy of direct transition, carriers are injected also to the Γ valley when the carriers are injected at high concentration even when complete direct transition is not attained and electrons and holes can perform direct transition type recombination. Patent Literature 3 (JP-T No. 2009-514231) discloses a technique of epitaxially growth of germanium applied with 0.25% tensile strain on silicon and injecting carriers at high concentration to emit light although it is not changed to the direct transition type thereby preparing a laser diode. The Non-Patent Literature 2 discloses a light emitting diode (hereinafter simply referred to as LED) prepared by using germanium epitaxially grown on silicon. Patent Literature 4 (JP-A No. 2007-173590) discloses a technique of preparing a light emitting element by applying a tensile strain to silicon. Further, Patent Literature 5 (JP-A No. 2009-76498) discloses a germanium laser diode using a Purcell effect caused by intensely confining light in germanium.

In addition to the method of using the tensile strain, a method called as valley projection of using silicon nanostructure has been known as a technique of changing an indirect transition semiconductor into a direct transition semiconductor.

Since a region where electrons move spatially is restricted for silicon in the nanostructure, the electron momentum is effectively decreased. In the material such as silicon or germanium, the direction of the momentum of electrons is determined based on the inherent band structure. The valley projection is a method of confining electrons in the nanostructure relative to the direction of the momentum of the electrons. As a result, the electron momentum is effectively reduced to 0. That is, this is a method of presumably changing into the direct transition type in which the valley of the energy of the conduction band is substantially at the Γ valley.

For example, in the band structure of silicon in the bulk state, since the bottom of the conduction band is present near the X point, the valley of the energy can be effectively defined at the Γ valley by using (100) face as the surface and reducing the film thickness of silicon, which can be changed presumably into a direct transition semiconductor. Further, in the case of germanium, since the conduction band bottom is present at the L valley in the bulk state, the valley of the energy can be defined effectively at the Γ valley by forming a thin film with a (111) face as the surface and can be changed presumably into a direct transition semiconductor. As disclosed in the Patent Literature 1 (JP-A No. 2007-294628), an element of emitting light from an extremely thin single crystal silicon at high efficiency has been invented by directly connecting an electrode to an extremely thin single crystal silicon having (100) face as the surface and injecting carriers in a direction horizontal to a substrate.

### CITATION LIST

### Patent Literature

Patent Literature 1: Japanese Unexamined Patent Application Publication No. 2007-294628

Patent Literature 2: Japanese Unexamined Patent Application Publication (Translation of PCT Application) No. 2005-530360

Patent Literature 3: Japanese Unexamined Patent Application Publication (Translation of PCT Application) No. 2009-514231

Patent Literature 4: Japanese Unexamined Patent Application Publication No. 2007-173590

Patent Literature 5: Japanese Unexamined Patent Application Publication No. 2009-76498

### Non-Patent Literature

Non-Patent Literature 1: F. Zhang, V. H. Crespi, Physical Review Letters, 102, 2009, p. 156401

Non-Patent Literature 2: X. Sun, J. Liu, L. C. Kimerling, J. Michel, Optics Letters, Vol. 34, No. 8, 2009, p. 1198

### SUMMARY OF THE INVENTION

### Technical Problem

As described above, a study of preparing a light emitting element by changing germanium into-the direct transition type as the light emitting element for intra-chip optical interconnection or inter-chip optical interconnection of silicon has been made.

While there is a method of applying tensile strain by epitaxial growth of germanium on silicon and injection of carriers at high concentration thereby emitting light from germanium, since the lattice constant difference between germanium and silicon is as large as about 4%, a number of threading dislocation of 10⁷/cm² or more is generated in germanium epitaxially grown on silicon.

As a result, the problem of degradation in the light emission characteristics or lowering of the reliability is inevitable. Accordingly, there is a subject of preparing a light emitting element using germanium with less threading dislocation for preventing degradation of the light emitting characteristics or lowering of reliability.

Further, while it is necessary to inject carriers at high concentration for emitting light from germanium by injecting electrons to the Γ valley, n-type doping at high concentration in germanium is difficult by the existent technique and it is difficult to effectively inject electrons in a light-emitting layer.

Accordingly, there is a subject of preparing a germanium light-emitting element in which electrons at high concentration can be injected into a light-emitting layer.

Further, when light is emitted from germanium by the valley projection, since, the light-emitting portion is thin and the light confinement layer is formed to the outside of the light-emitting portion, it is difficult to increase coupling between the light-emitting portion and light.

Accordingly, in order to form an inverted distribution more simply to cause stimulated emission, there is a subject of increasing a light confinement coefficient and, at the same time, preparing a germanium light-emitting element of large coupling between the light-emitting portion and light.

As another cause for degrading the light-emitting characteristics, there is a phenomenon of free carrier absorption that light is absorbed by free carriers in crystals. When germanium doped with an impurity at high concentration is contained in the core of a waveguide channel, this causes a problem that emitted light is absorbed by a plurality of free carriers present in the electrode to increase a threshold current for laser oscillation. Accordingly, there is a subject of preparing a germanium light-emitting element with less free carrier absorption by the electrode.

Further, a precise control for the magnitude of the applied tensile strain is difficult in the method of applying the tensile strain by the crystal growing of germanium on silicon.

Accordingly, there is a subject of preparing a germanium light-emitting element in which the strain applied to germanium as a light-emitting layer can be controlled accurately.

Further, since threading dislocation generated in germanium crystals forms defects in a direction perpendicular to the substrate, it is liable to be fractured upon application of voltage in a direction perpendicular to the substrate. Accordingly, there is a subject of preparing a germanium laser diode of a system of injecting carriers in a direction horizontal to a substrate in order to prevent degradation of the device reliability by the threading dislocation.

Then, an object of the present invention is to provide a germanium light-emitting element emitting light at a high efficiency by using germanium of a low threading dislocation density.

Alternatively, it intends to provide a germanium light-emitting element at high efficiency by injecting carriers at a high concentration into a light-emitting layer.

Alternatively, it intends to provide a germanium light-emitting element capable of easily forming an inverted distribution by a structure of confining light intensively and suppressing light absorption due to the electrode.

Alternatively, it intends to provide a germanium light-emitting element capable of accurately controlling the magnitude of tensile strain applied to germanium.

Alternatively, it intends to provide a germanium light-emitting element in which degradation of the reliability of a device due to threading dislocation is suppressed by injection of carriers in a horizontal direction.

### Solution to Problem

The outline of typical inventions among those disclosed in the present invention is simply described as below.

A germanium light-emitting element according to the present invention is a germanium laser diode formed over an insulator, having threading dislocation in a light-emitting layer of 1×10^{cm}² or less and using silicon or silicon germanium doped with an n-type impurity at high concentration for an n-type electrode, in which a light-emitting portion forms a core of a waveguide channel and can intensely confine light in a light-emitting layer with fewer free carriers.

Alternatively, the germanium light-emitting element according to the present invention is a germanium laser diode in which the magnitude of an applied tensile strain can be controlled by providing a member capable of applying an external stress.

Alternatively, a germanium light-emitting element according to the present invention is a germanium laser diode in which carriers can be injected in a horizontal direction and degradation in the reliability due to threading dislocation is suppressed.

The technique for germanium light-emitting element generally includes two techniques. One of them is a technique of emitting light by direct transition of germanium due to quantum effect of the valley projection.

The other is a technique of injecting electrons at high concentration into germanium epitaxially grown on silicon thereby injecting electrons not only to the L valley but also to the Γ valley of a conduction band and causing direct transition.

The germanium epitaxially grown on silicon has an advantage that a tensile strain is applied and germanium can be made closer to a direct transition type semiconductor. On the other hand, since lattice constant is different by as much as 4% between silicon and germanium, a layer amount of threading dislocation is generated and germanium single crystals at high quality cannot be used for the light-emitting layer.

According to the present invention, a germanium laser diode having a germanium light-emitting layer at high quality is attained by using germanium formed on silicon dioxide.

Further, a germanium laser diode exceeding the limit of the carrier concentration that could be injected in the existent n-type germanium can be provided by using silicon for the n-type electrode.

### Effect of the Invention

The effects obtained by typical invention among those disclosed in the present application are simply described as below.

In the germanium laser diode according to the present invention, since germanium is formed over an insulator and germanium single crystals at a threading dislocation density of 1×10⁶/cm² or less can be used as the light-emitting layer, a germanium laser diode that can be applied with high current and high voltage can be prepared.

Alternatively, the germanium light-emitting element according to the present invention can attain a carrier concentration as high as 5×10²⁰/cm³ or more by using silicon doped at high concentration or silicon germanium as an n-type electrode.

Alternatively, since the germanium light-emitting element according to the present invention can confine light in a ridged germanium light-emitting layer, an intense light confinement coefficient and a large coupling coefficient between a light-emitting layer and light can be obtained.

Alternatively, in the germanium light-emitting element according to the present invention, the tensile strain can be applied at good controllability by external stress.

Alternatively, in the germanium light-emitting element according to the present invention, degradation of the device reliability caused by threading dislocation can be suppressed by injecting carriers in the horizontal direction.

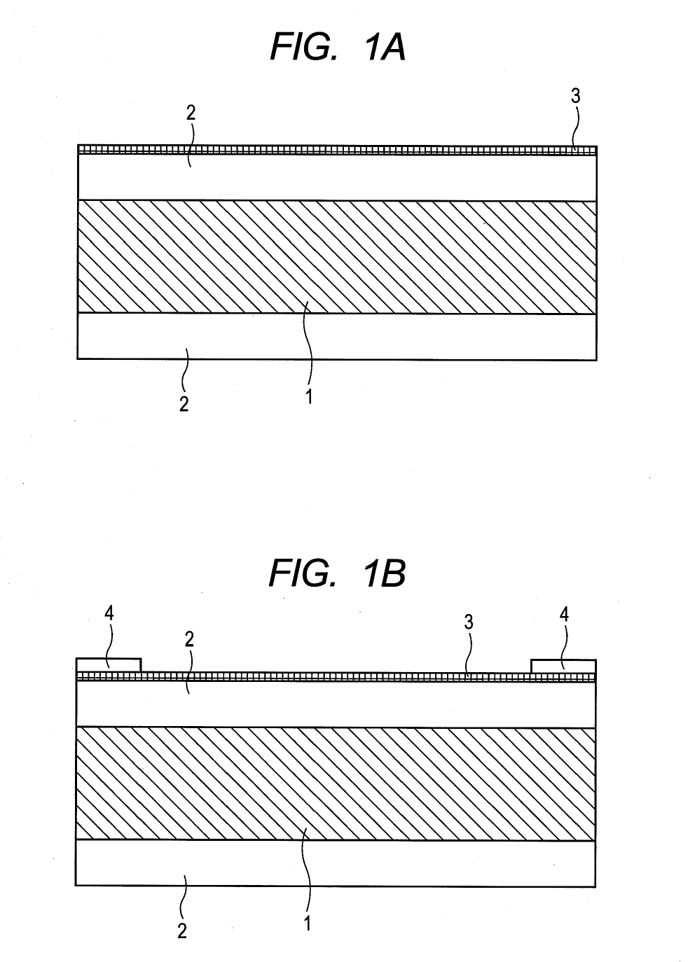

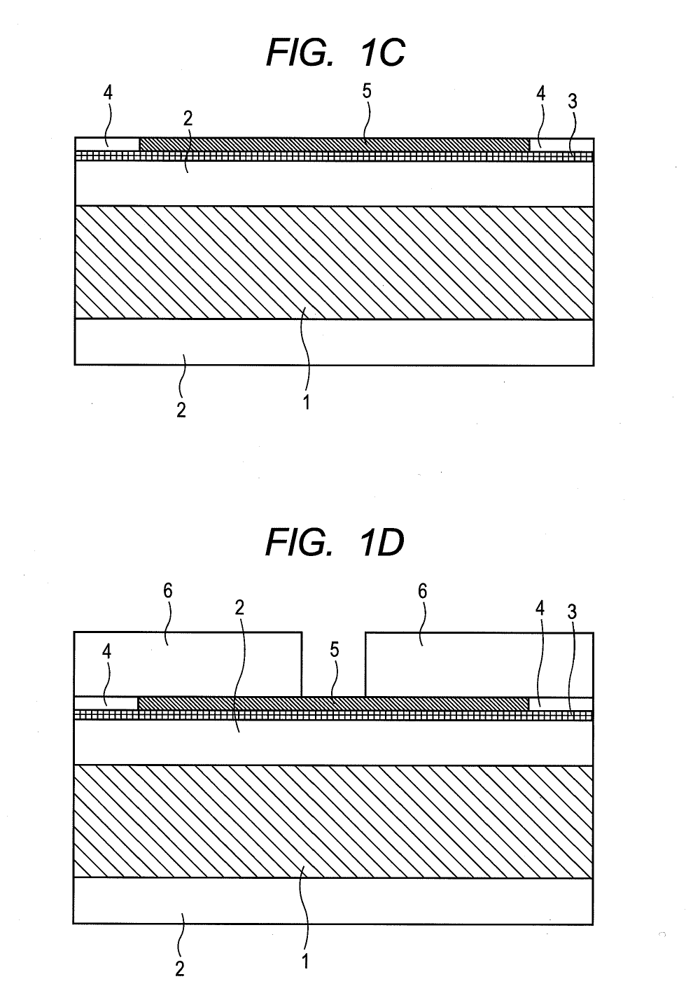

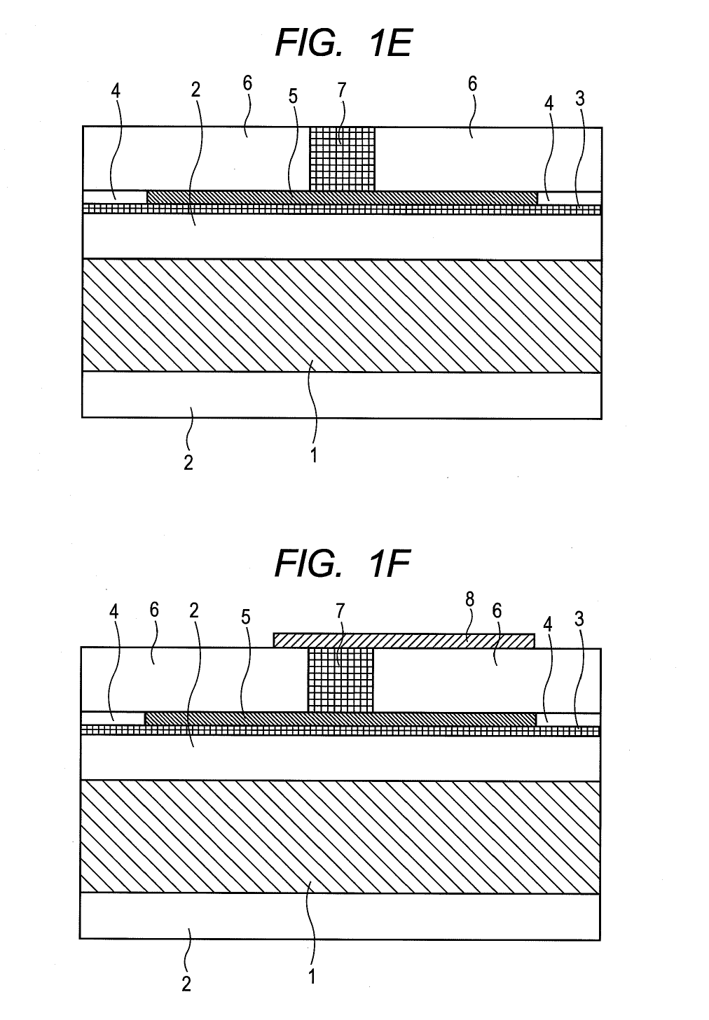

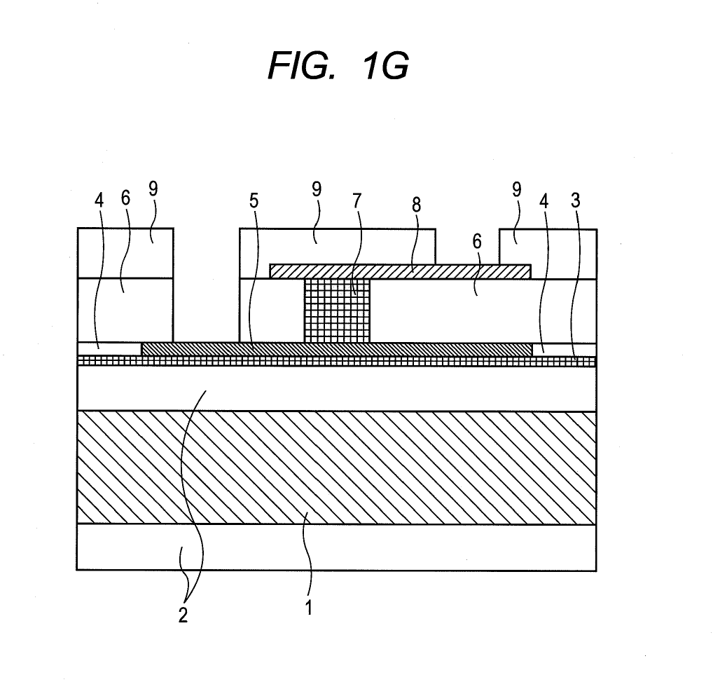

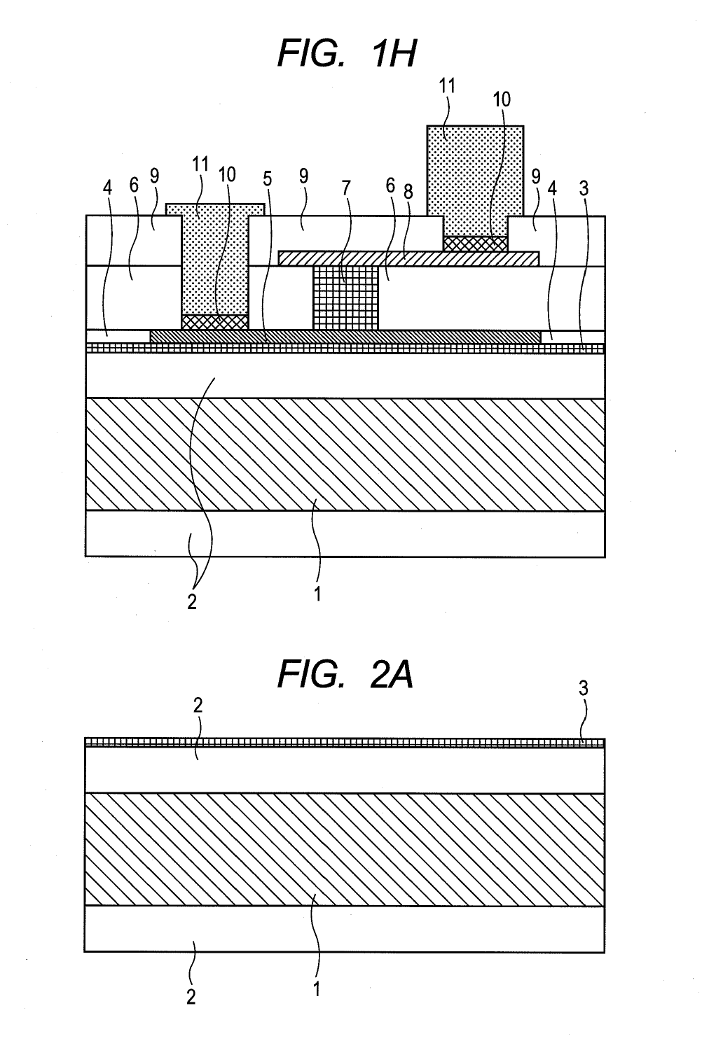

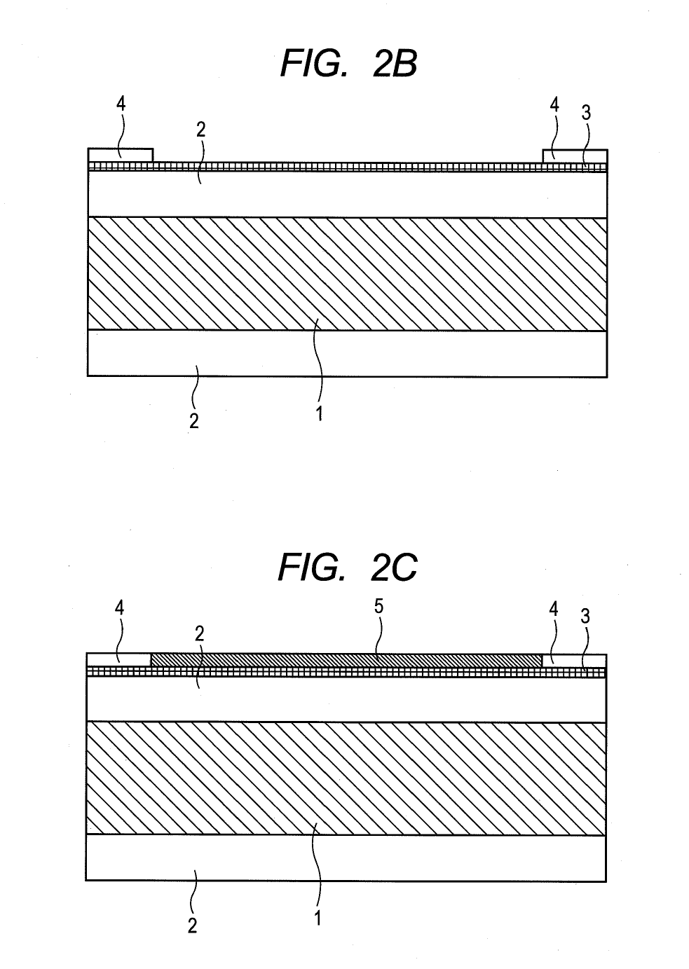

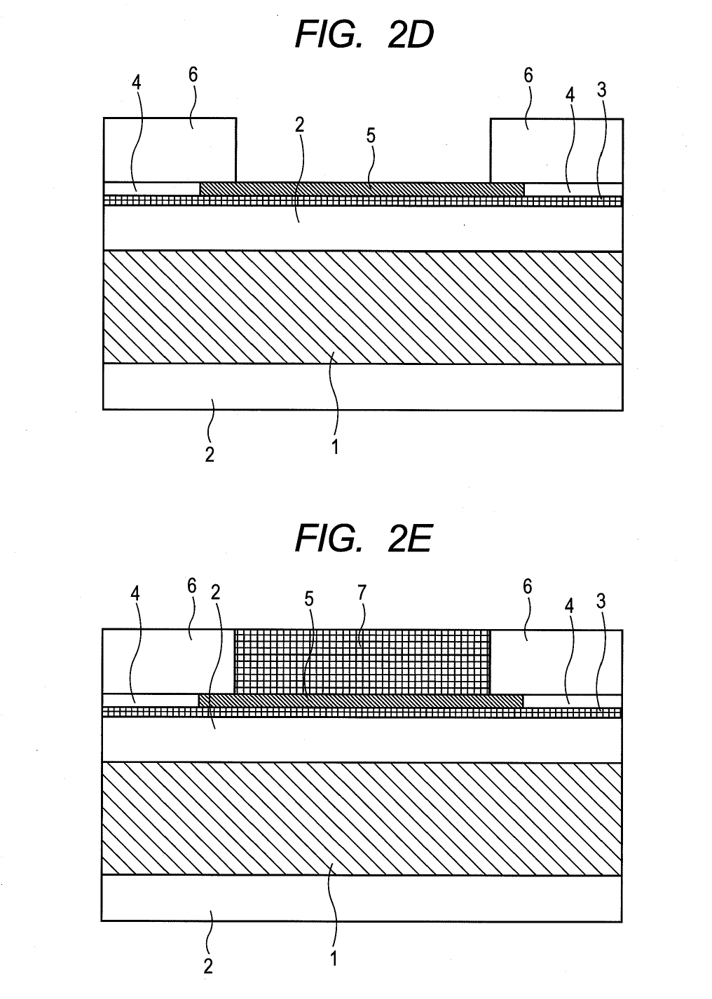

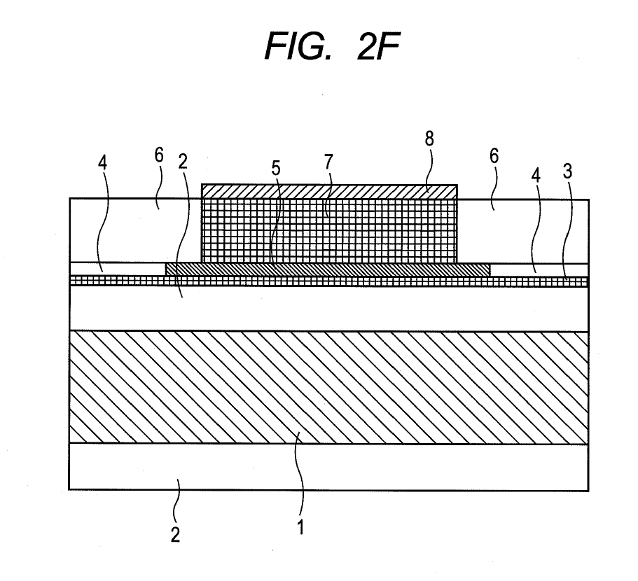

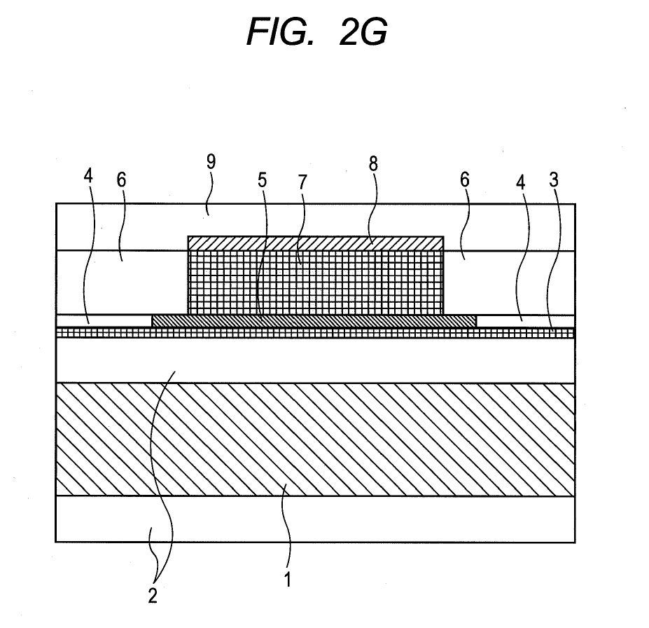

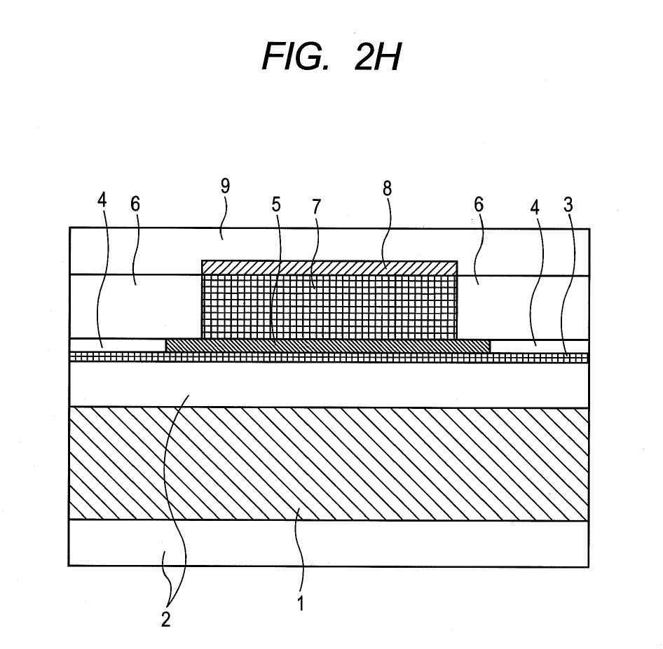

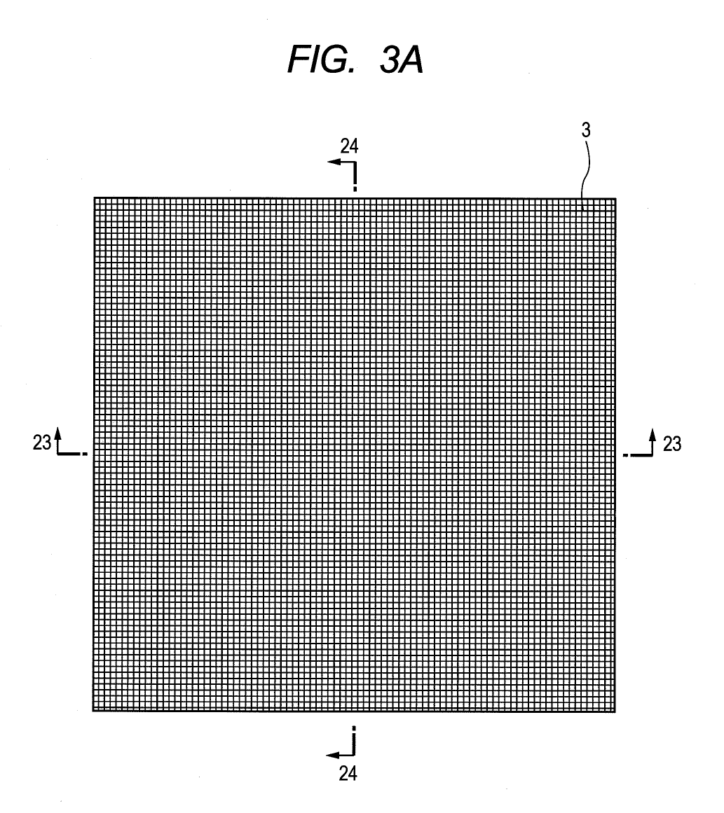

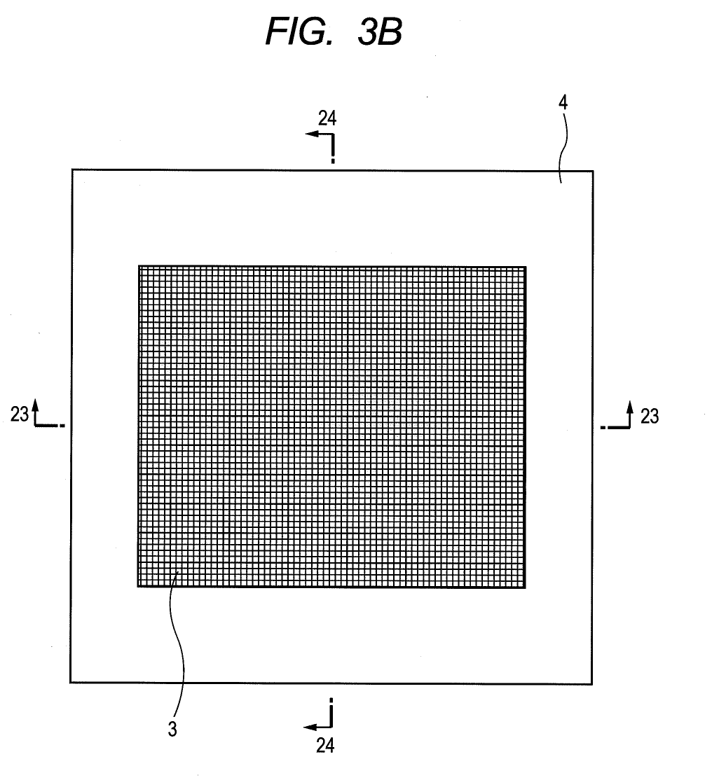

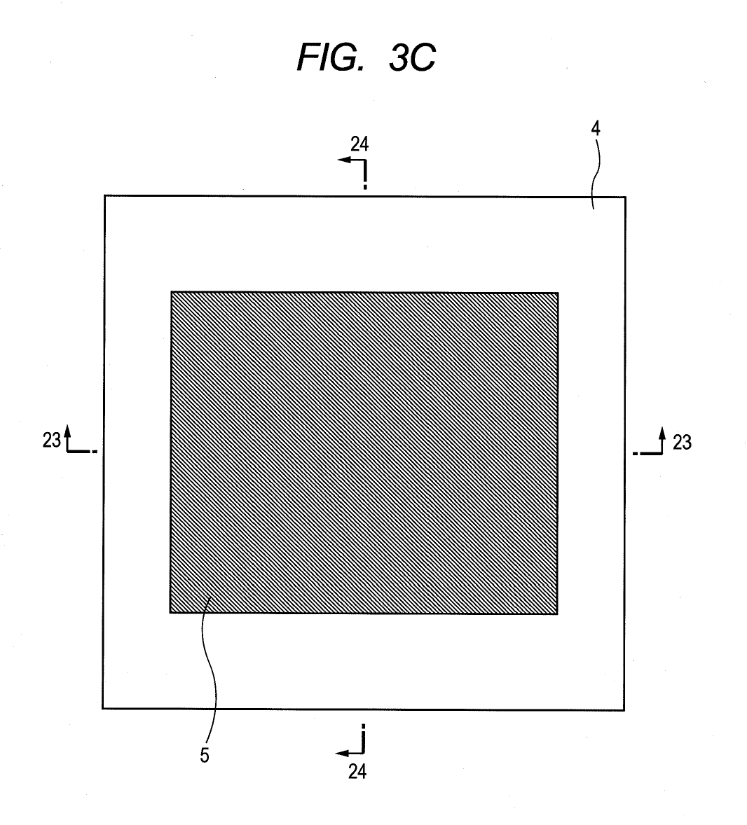

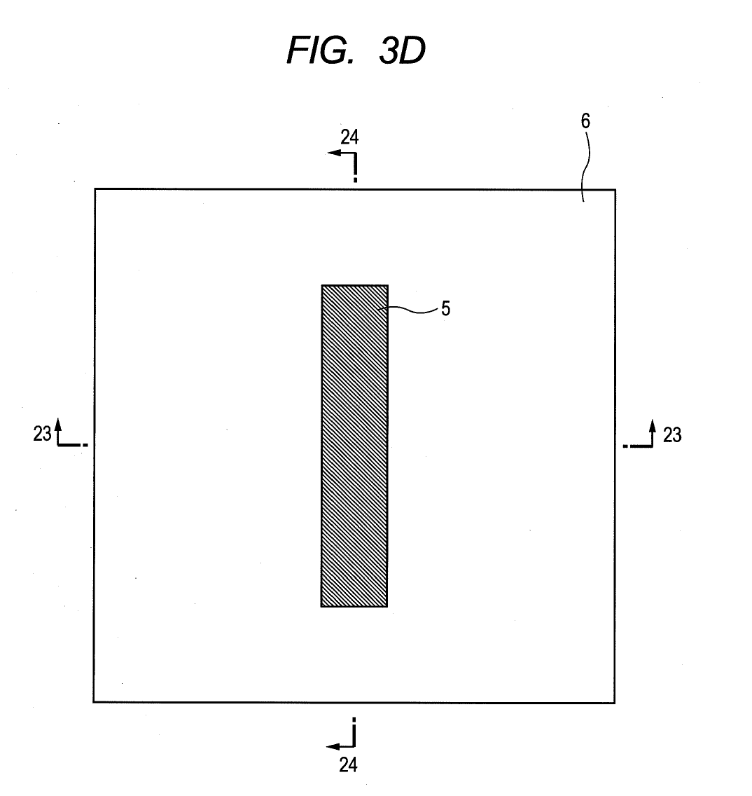

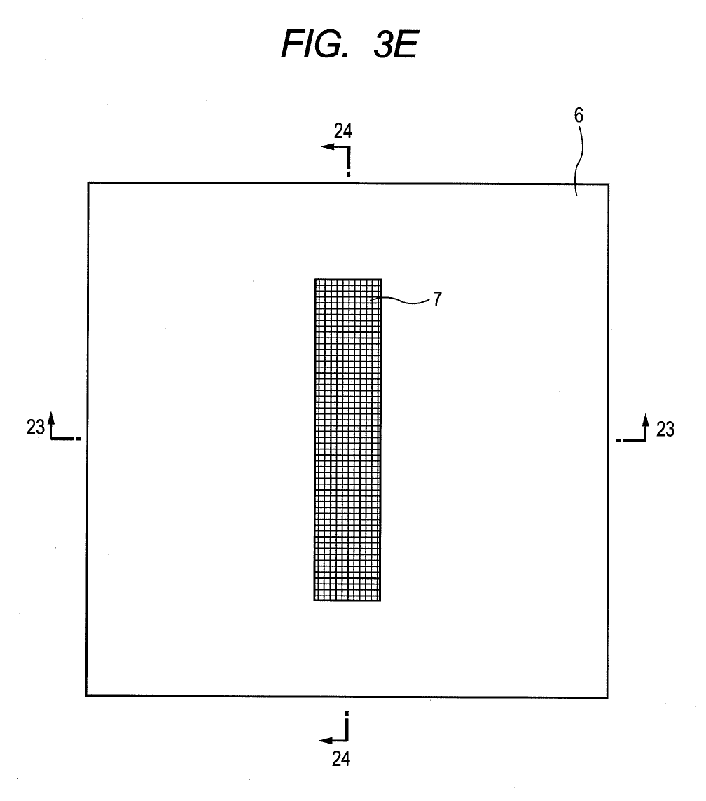

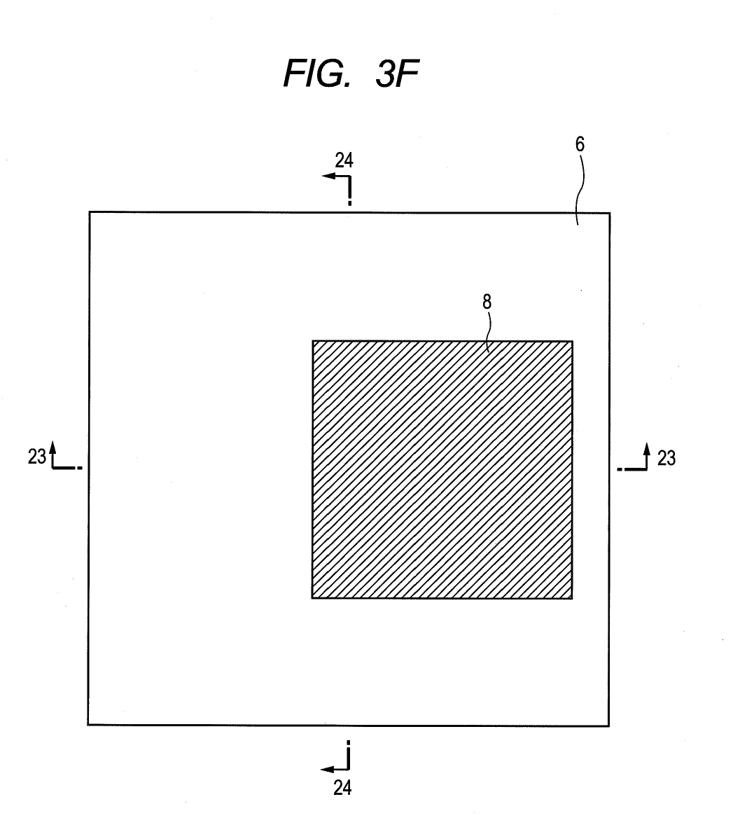

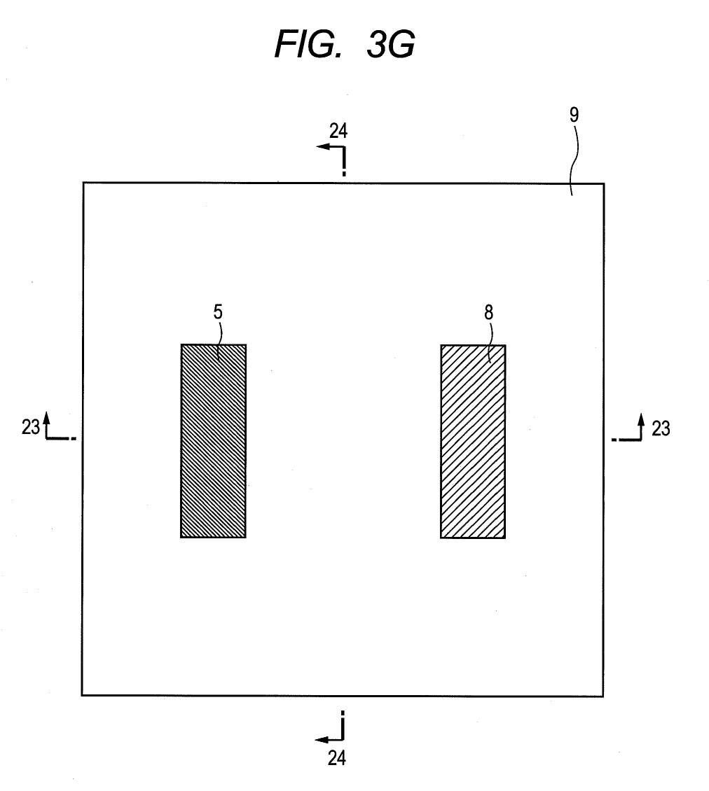

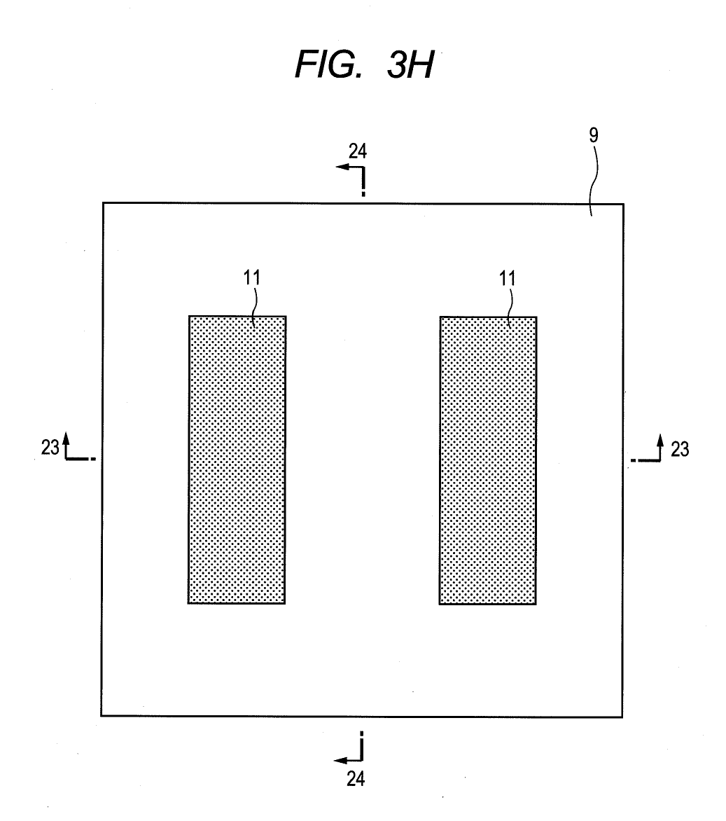

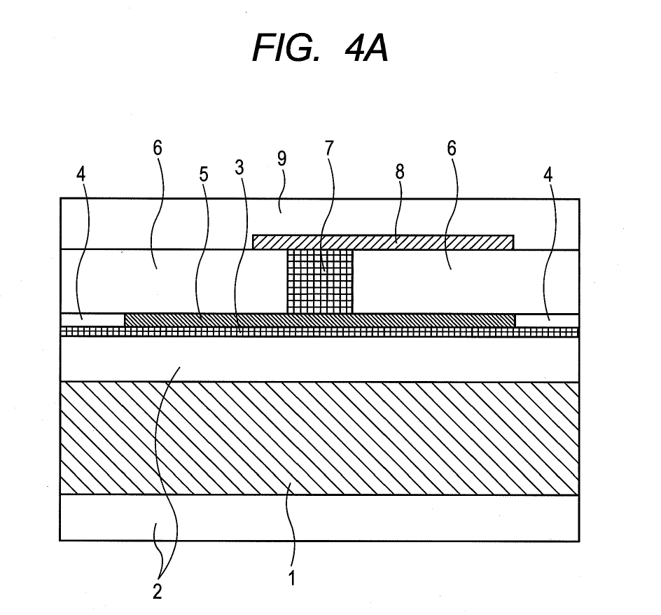

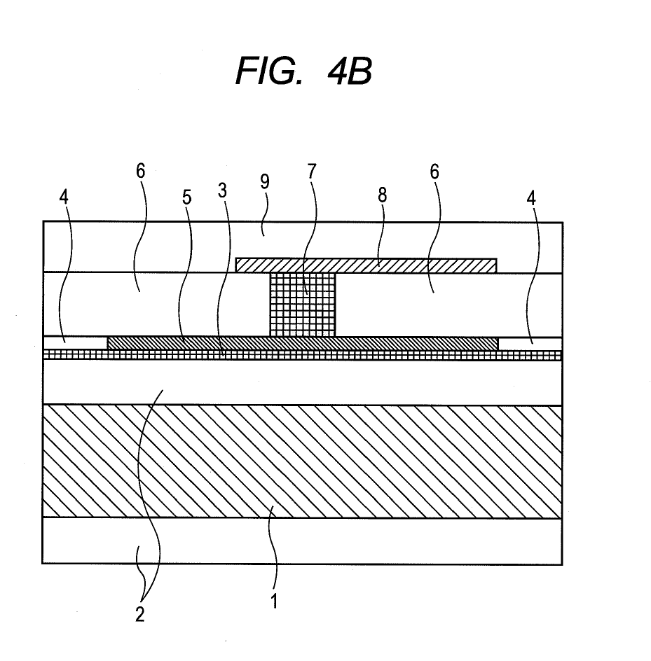

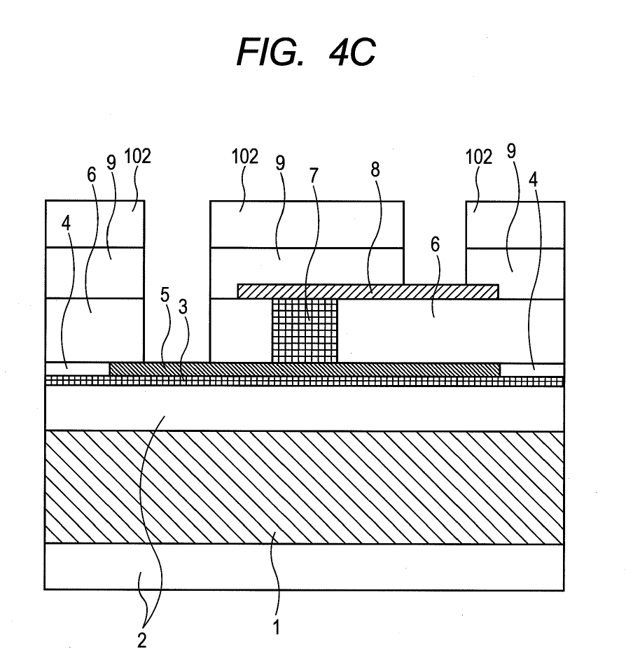

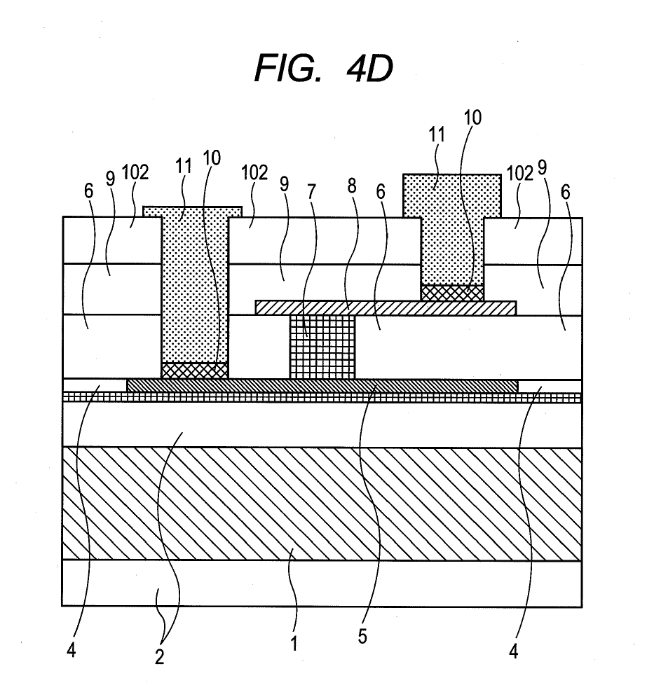

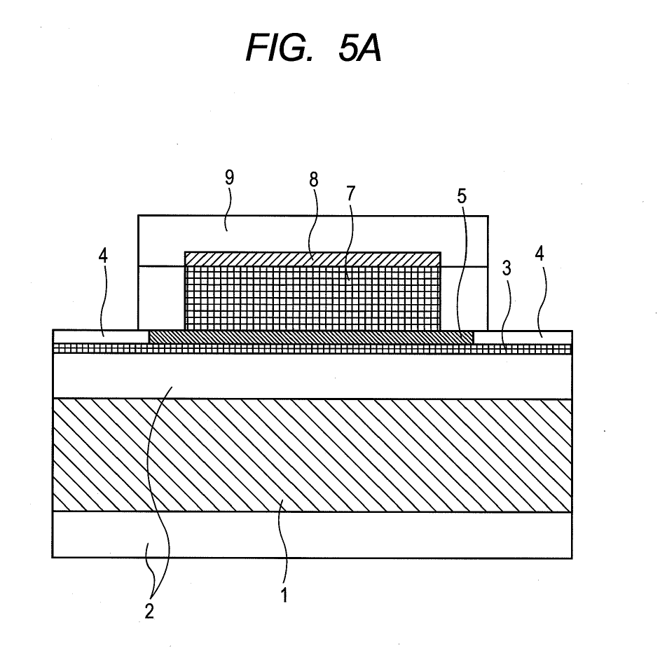

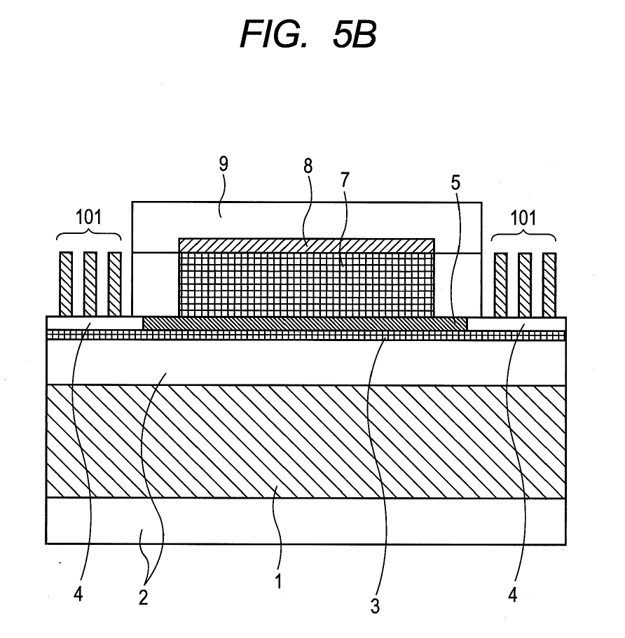

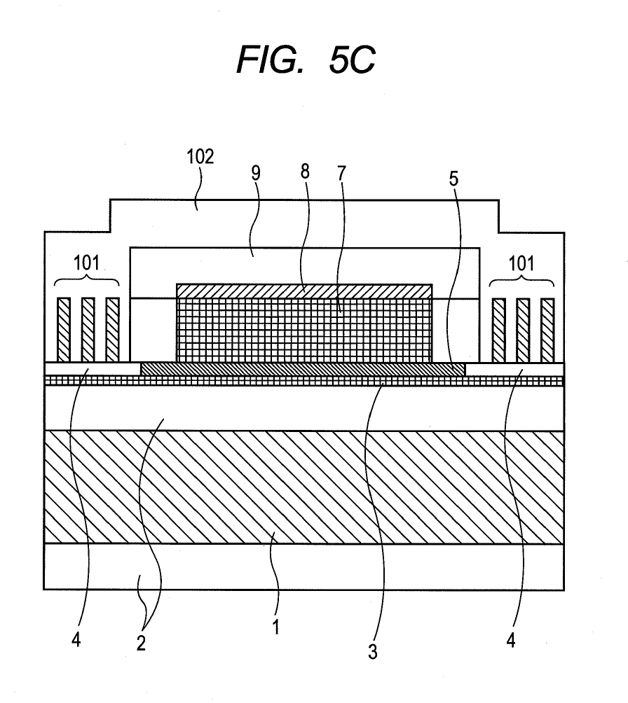

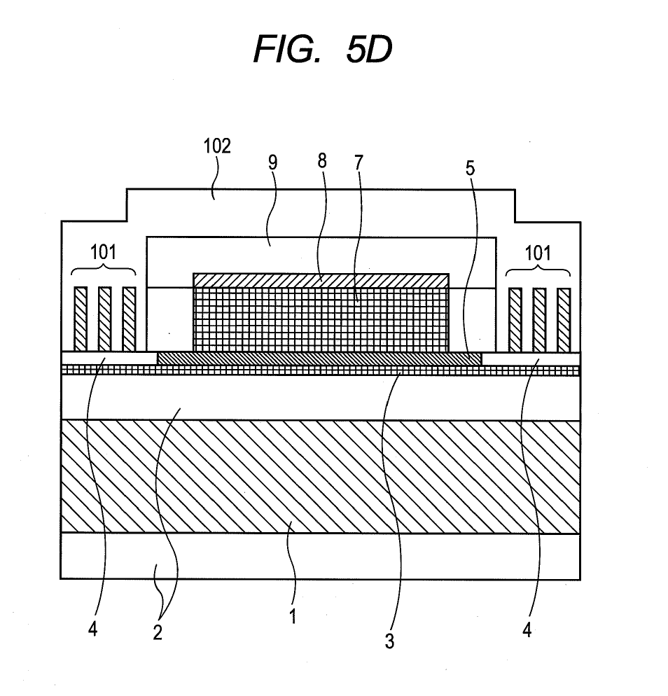

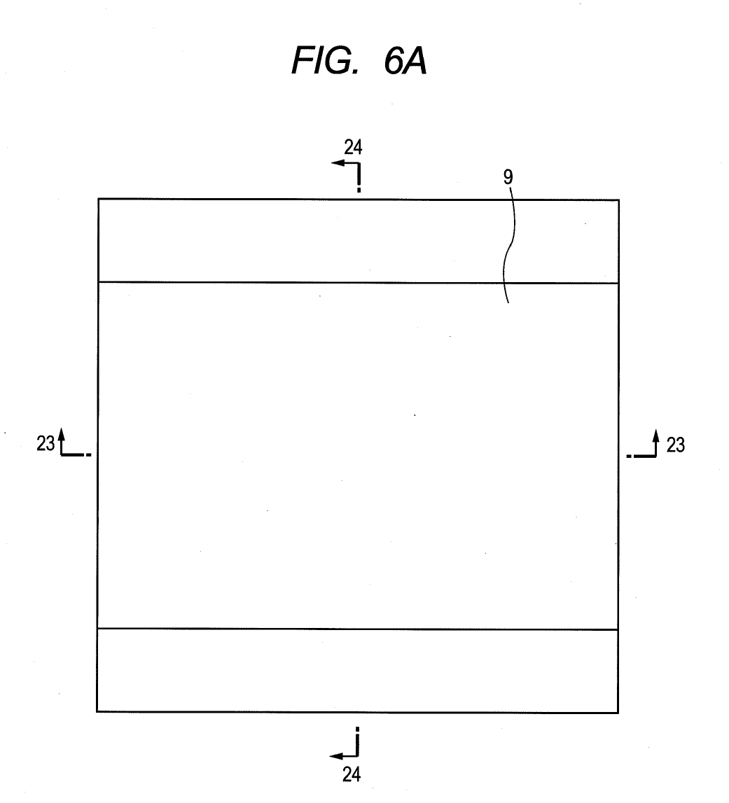

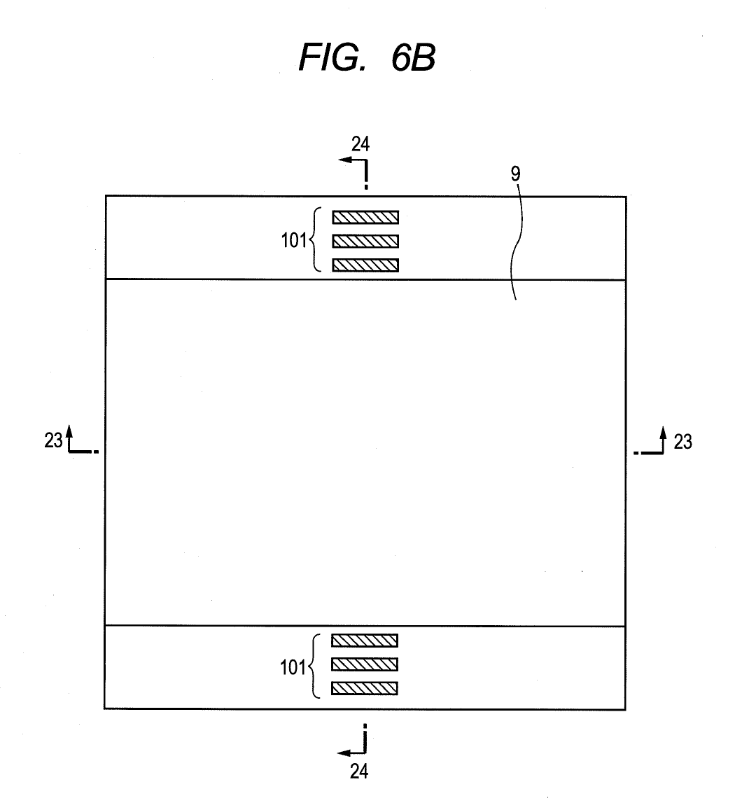

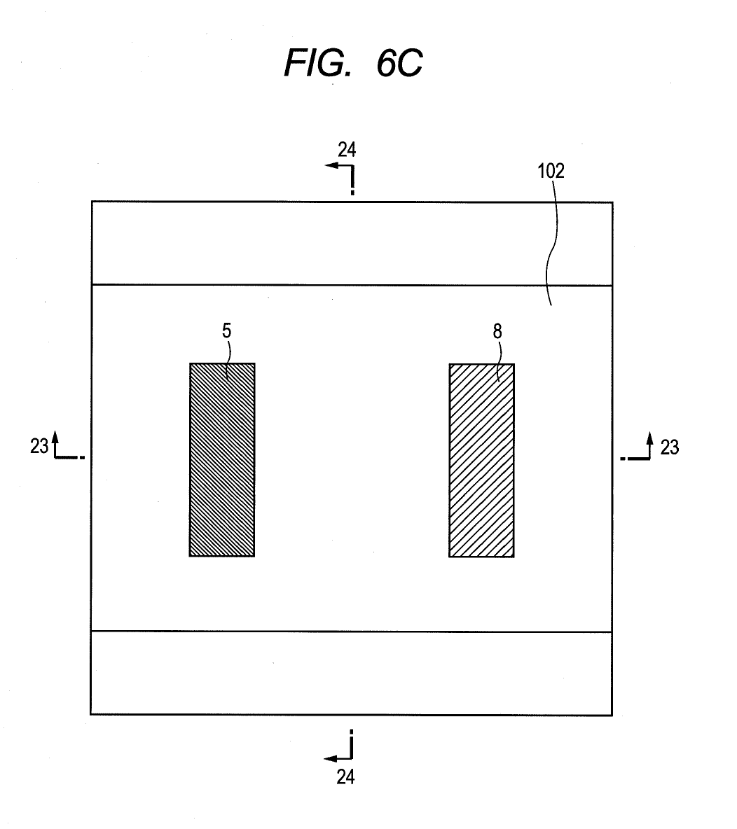

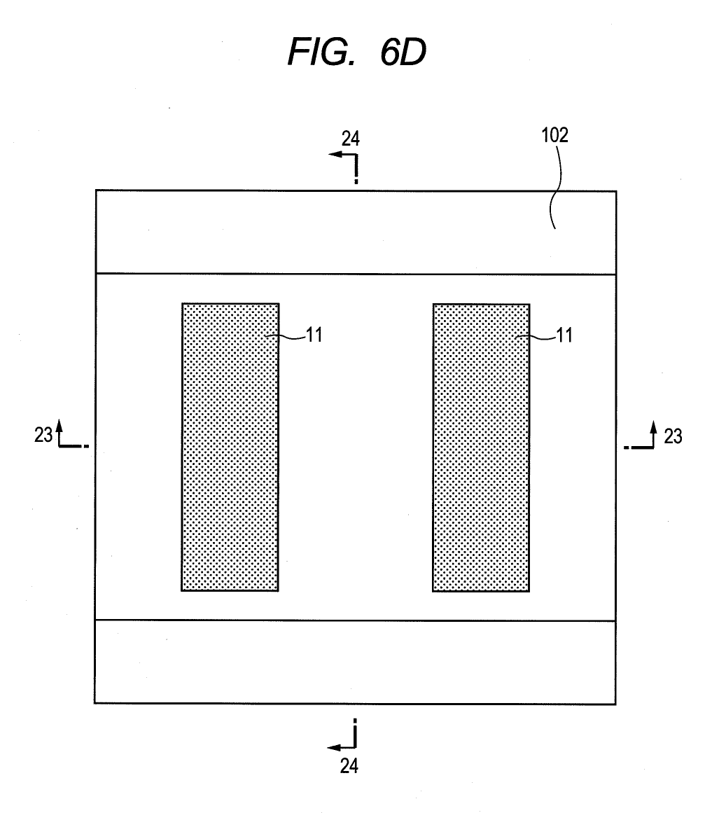

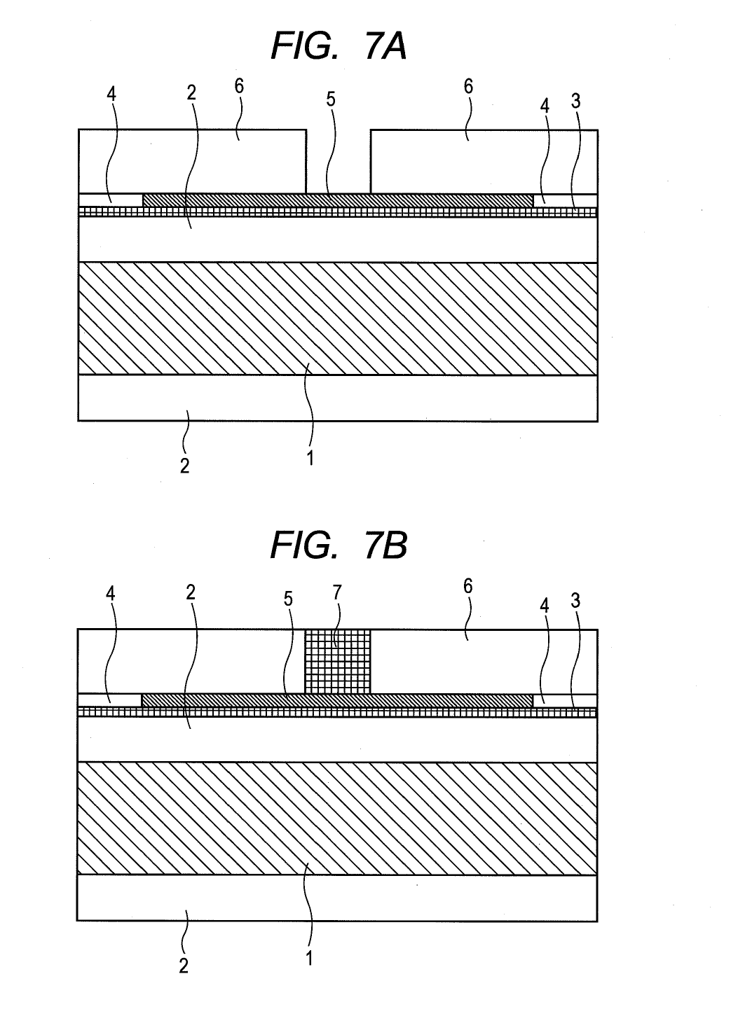

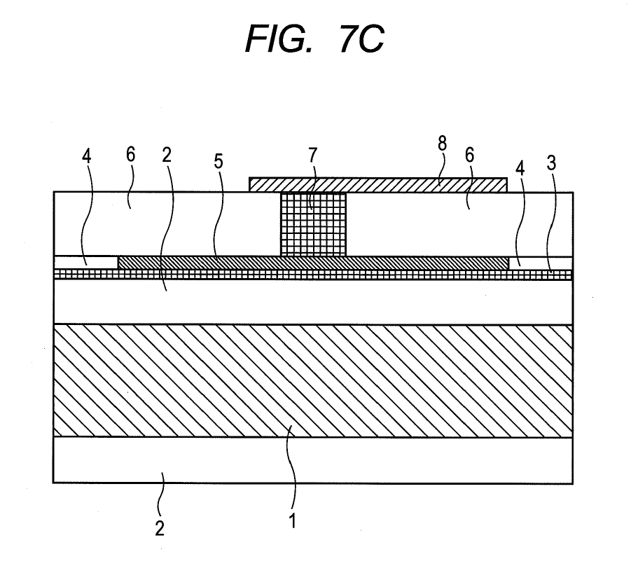

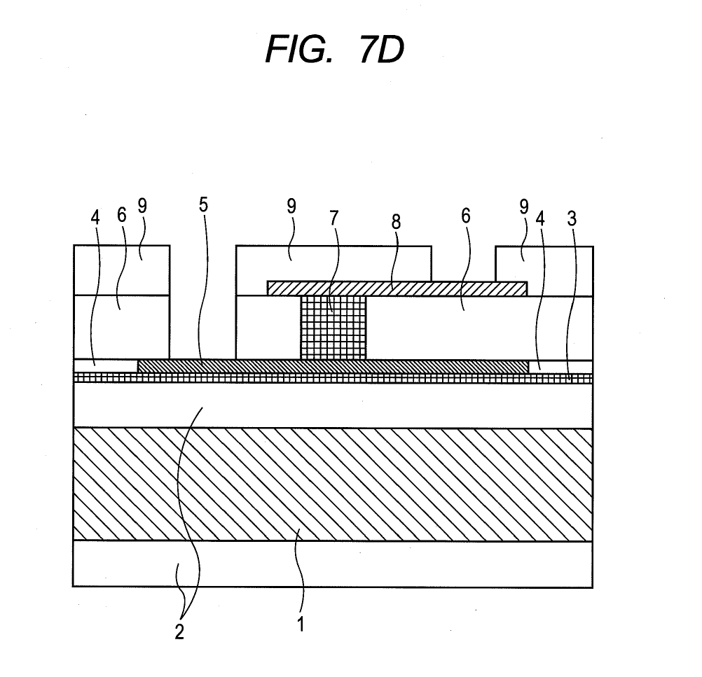

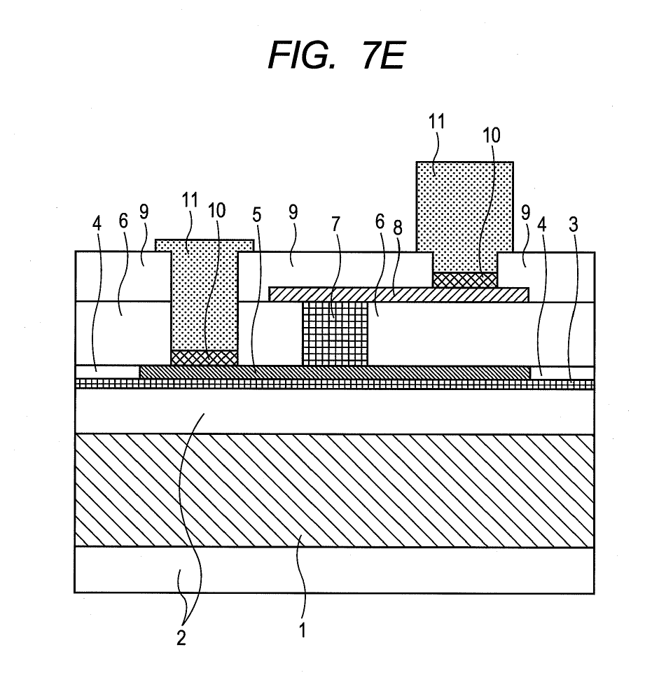

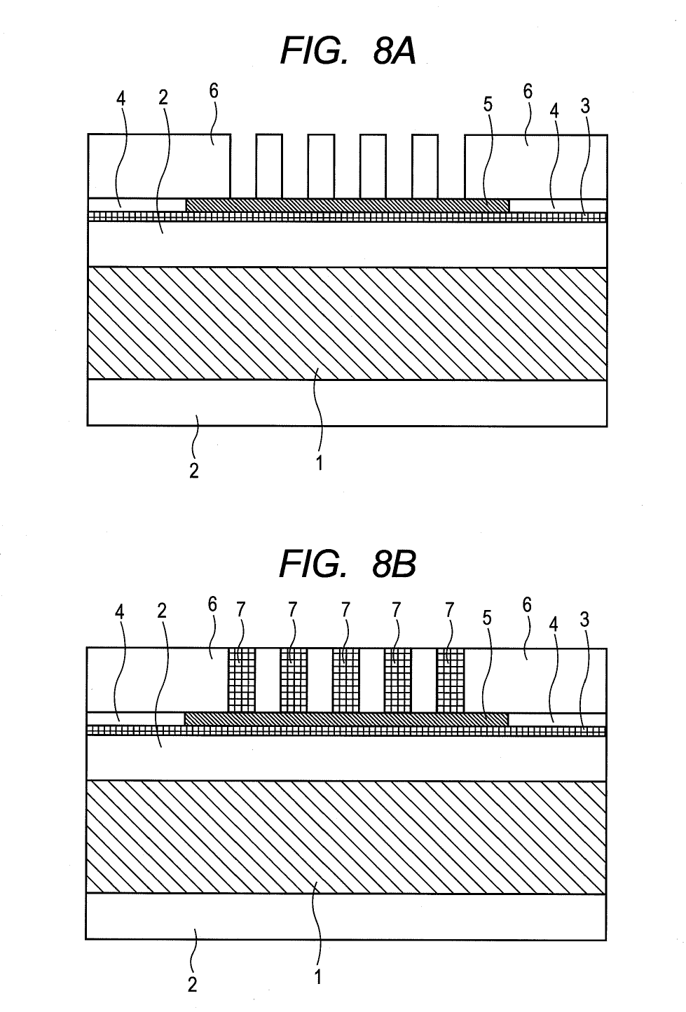

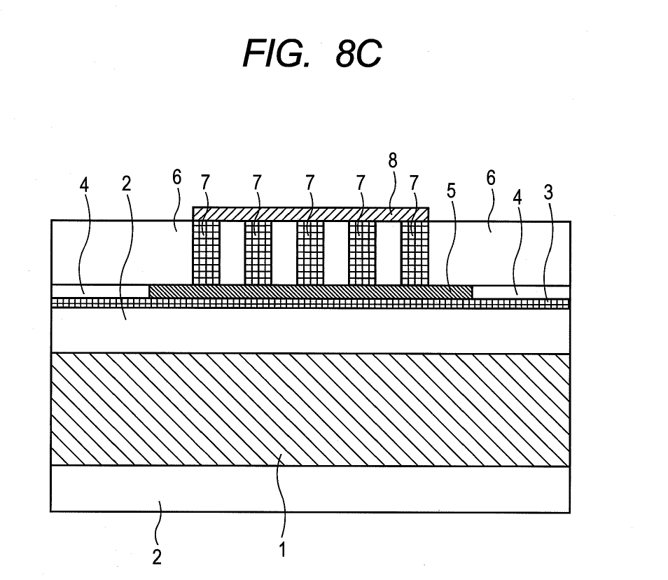

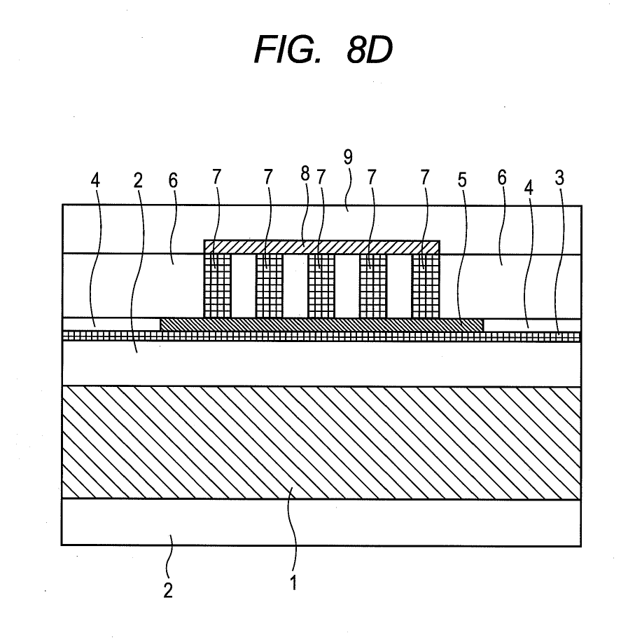

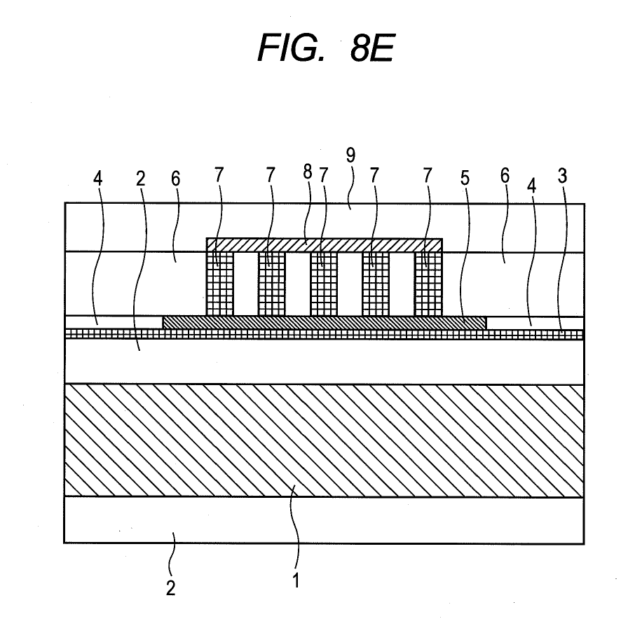

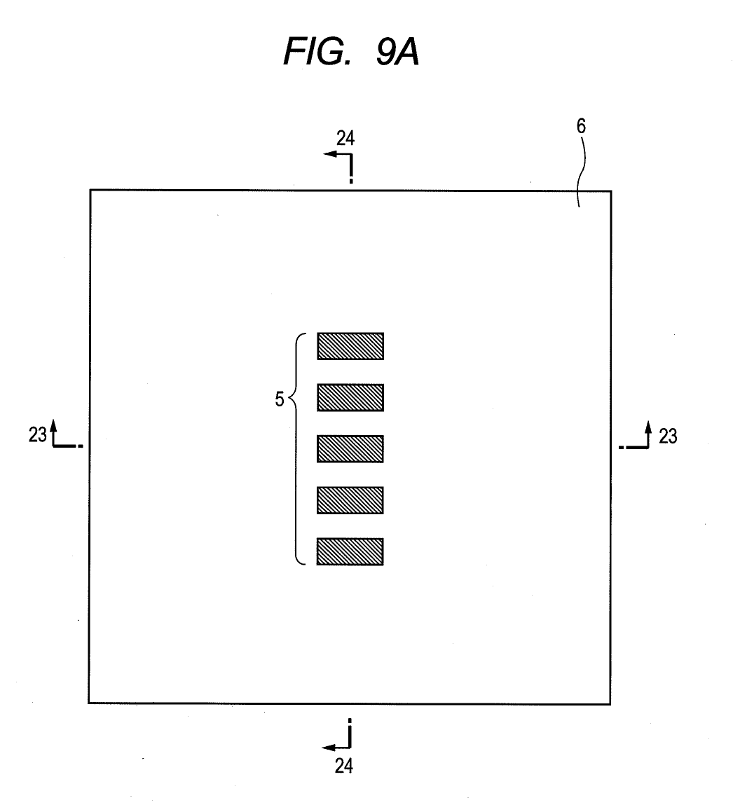

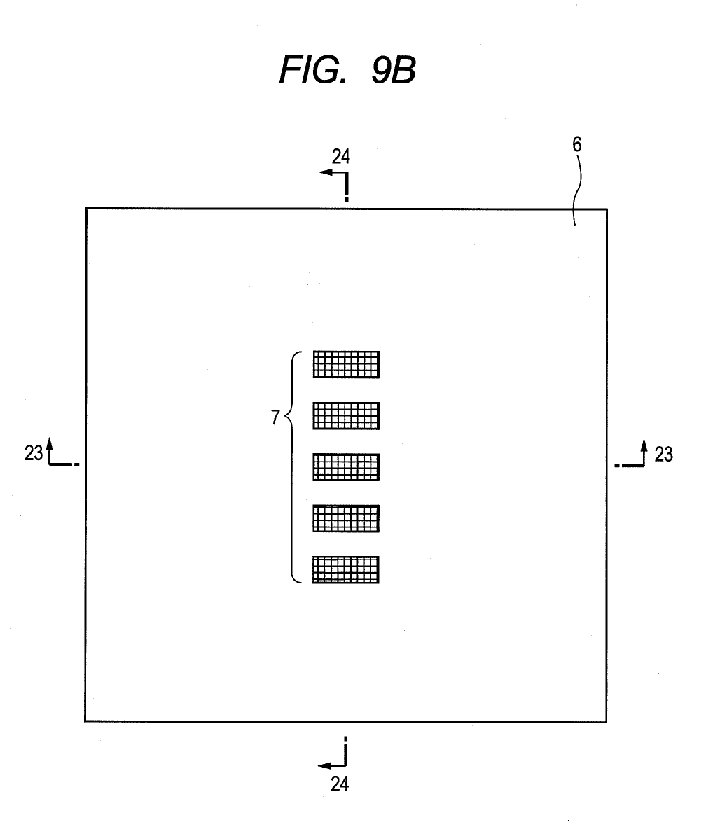

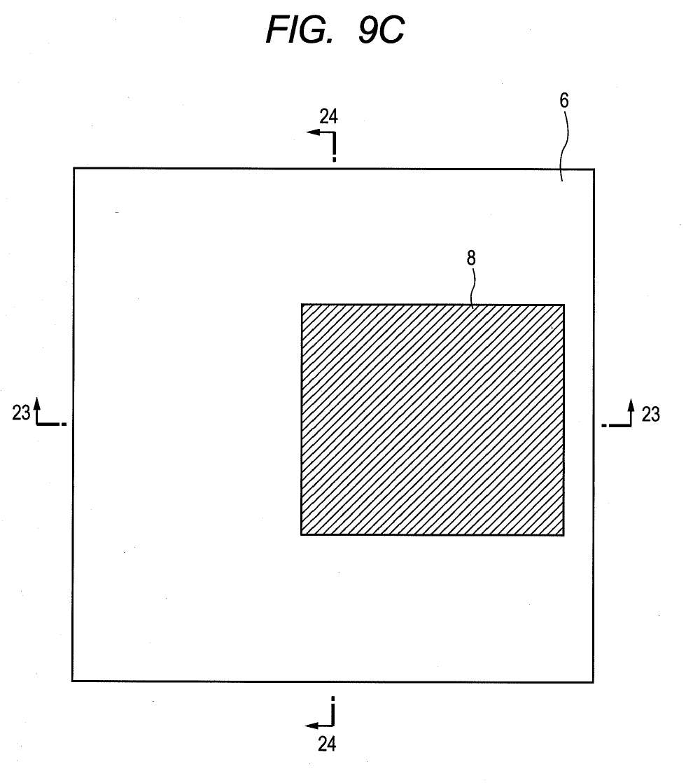

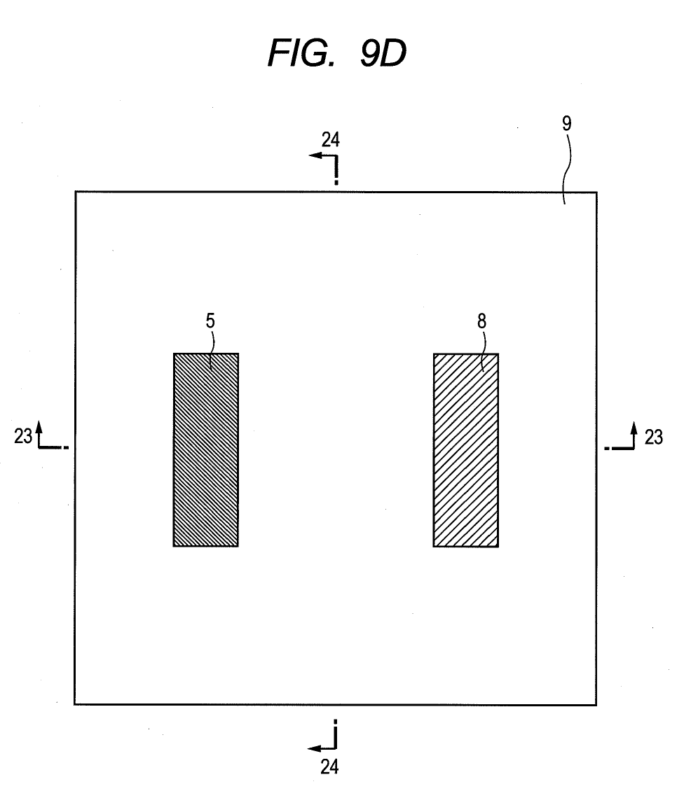

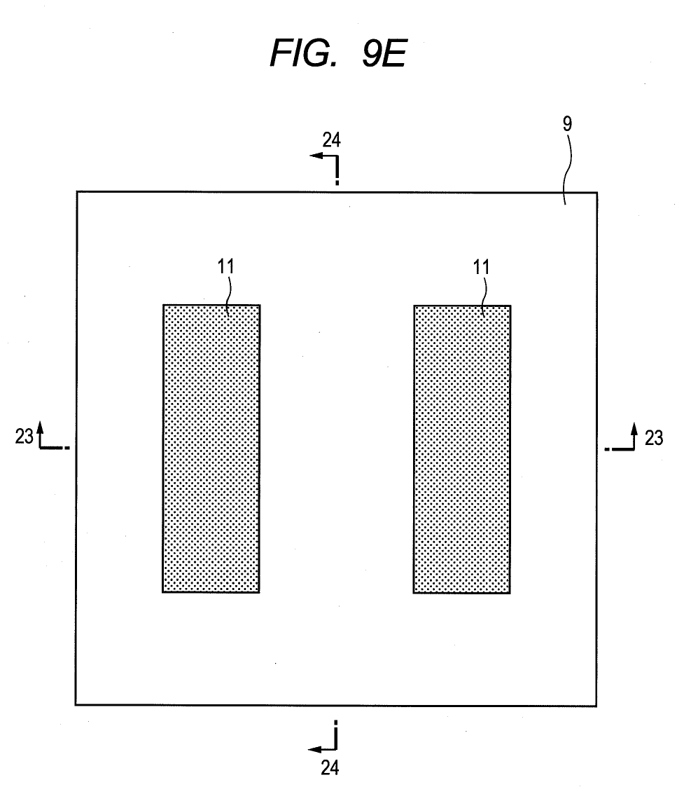

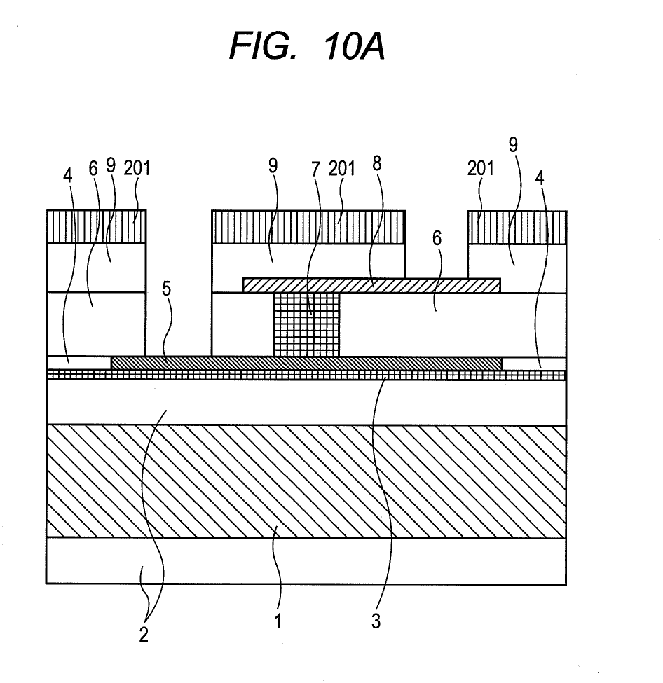

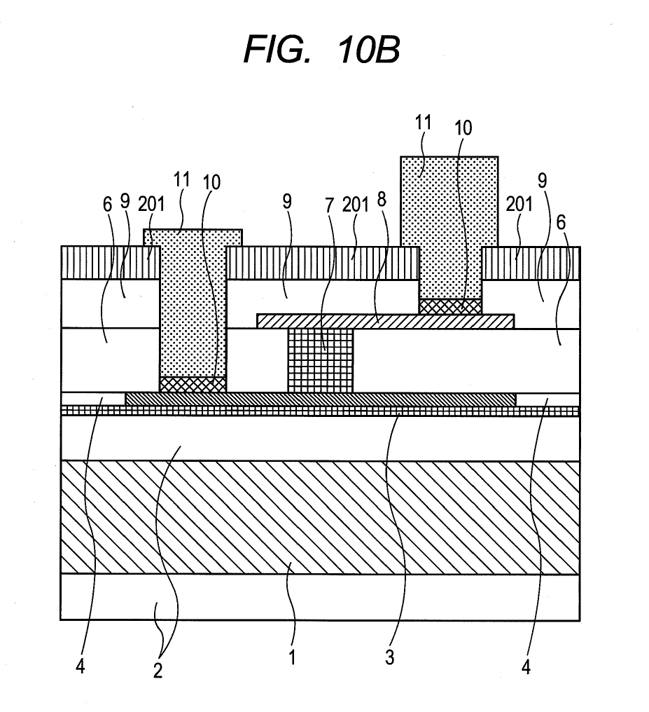

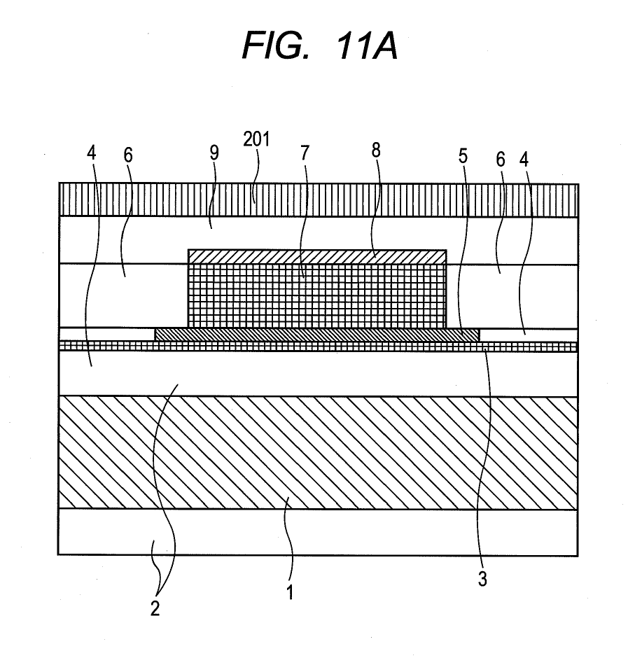

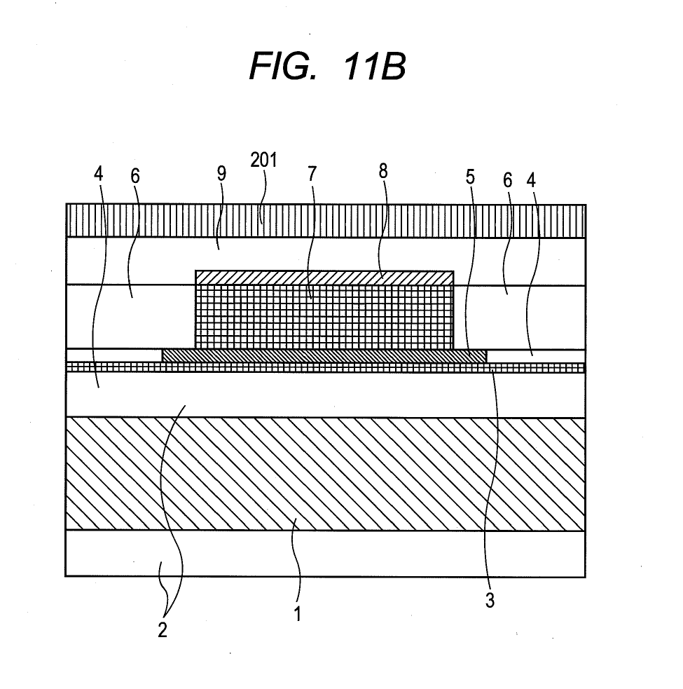

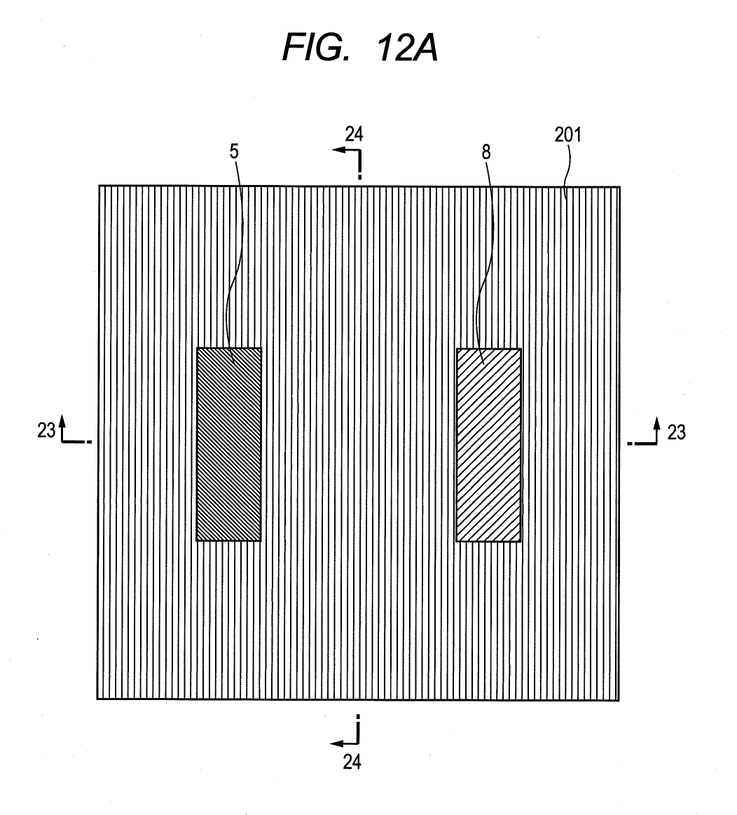

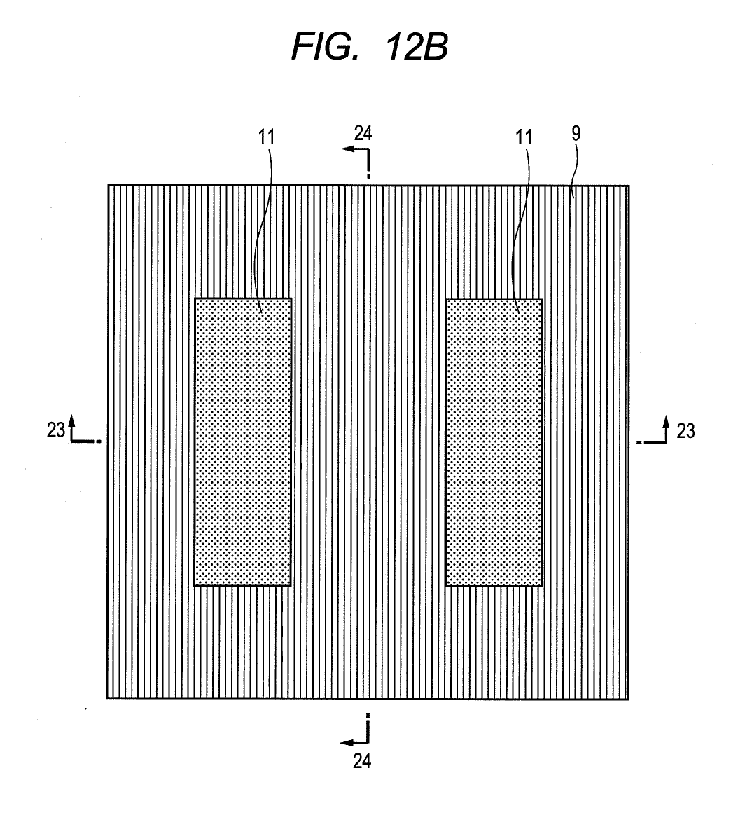

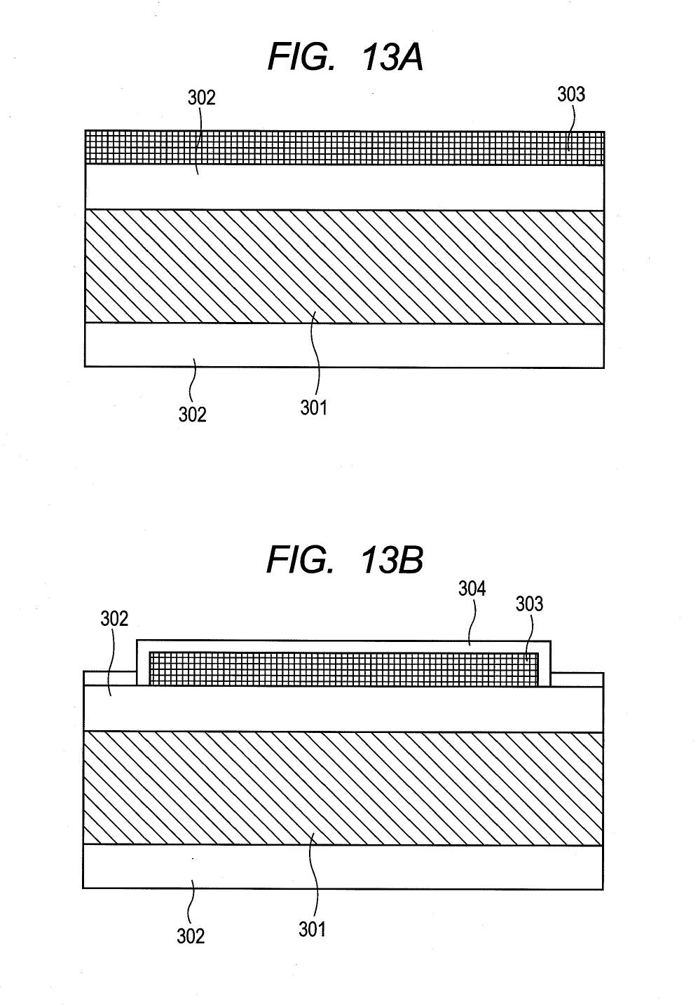

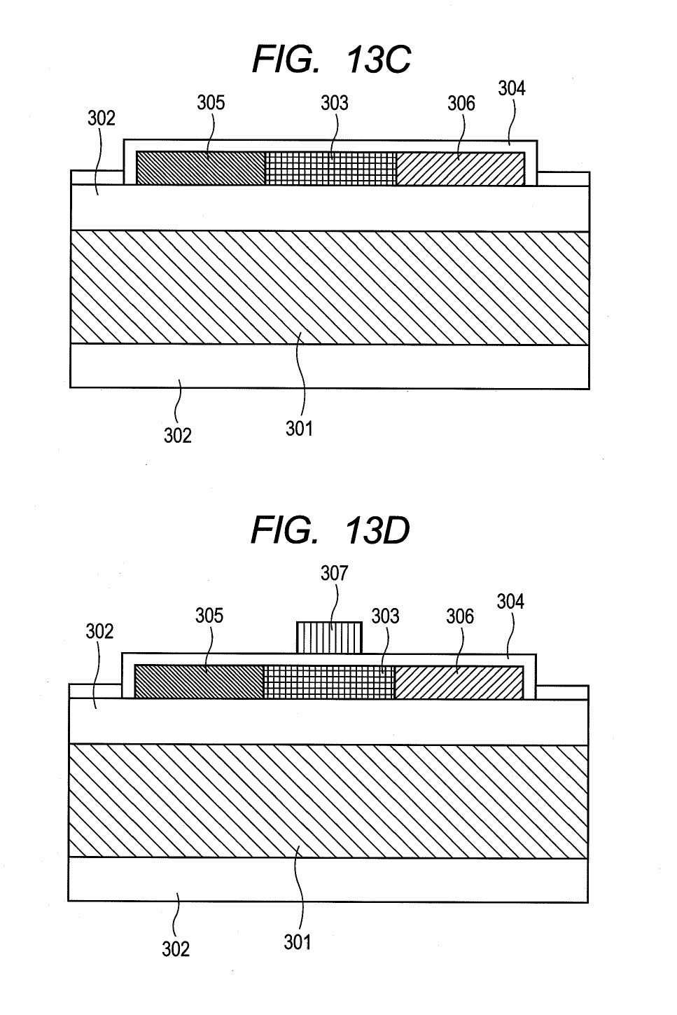

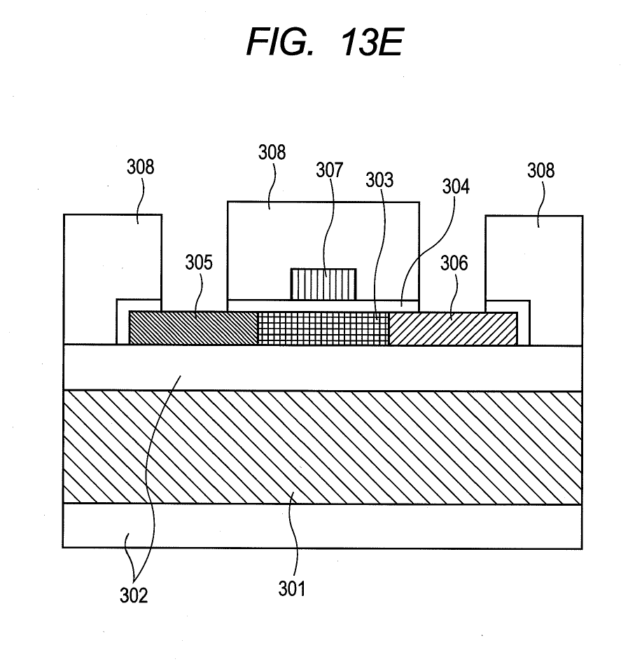

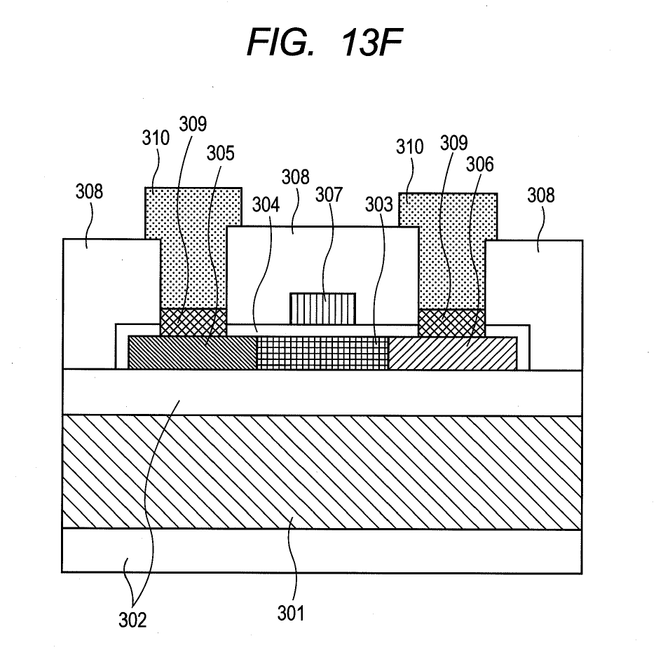

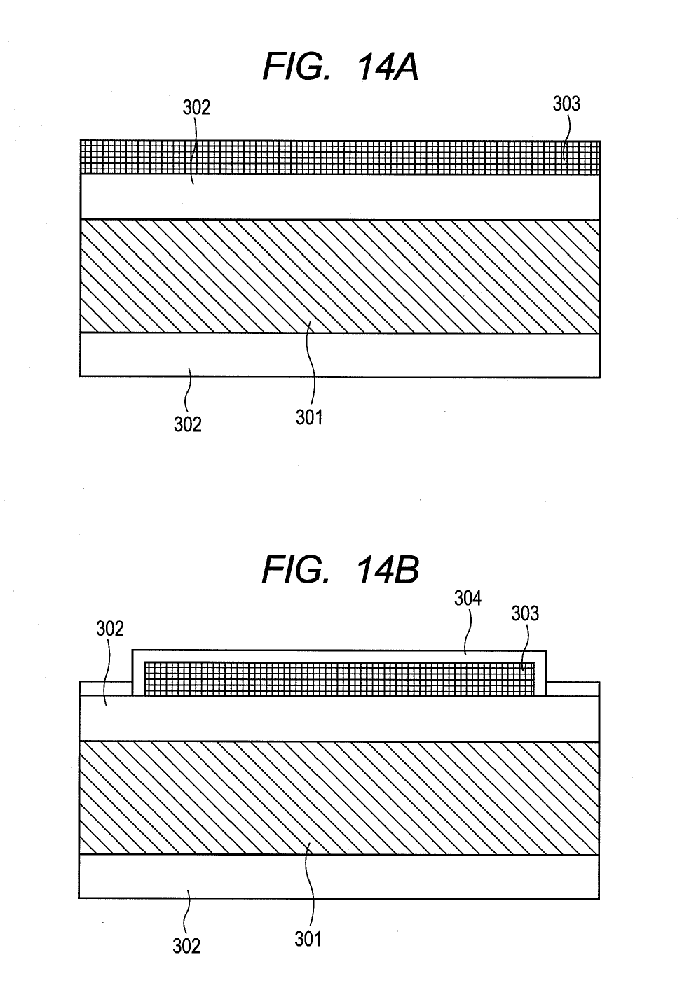

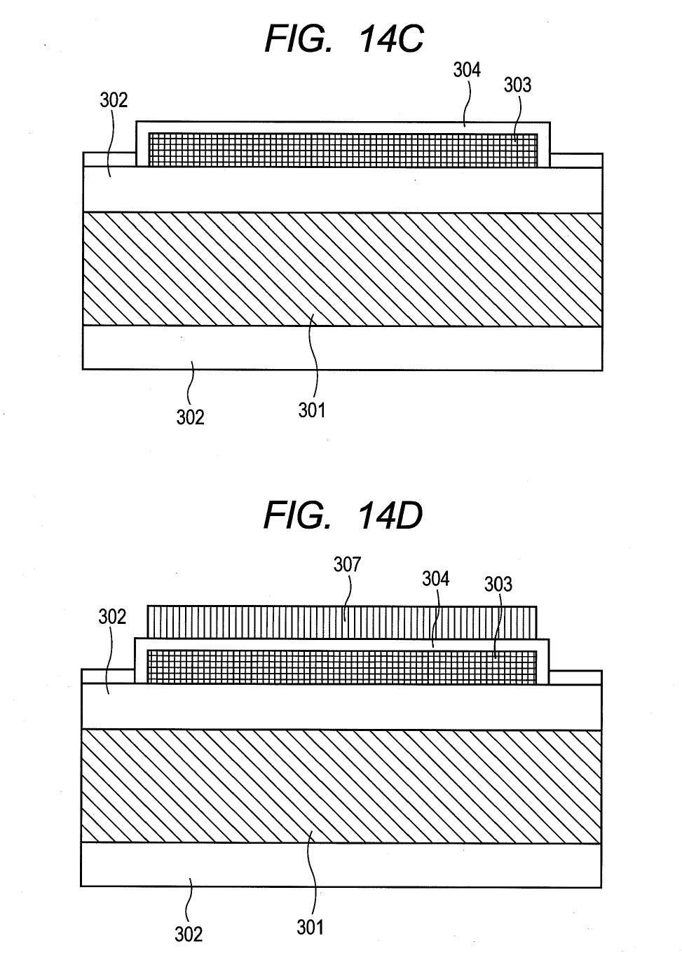

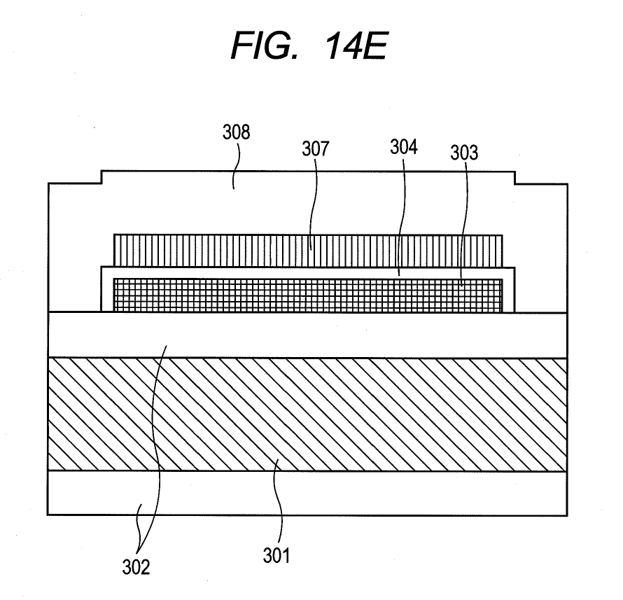

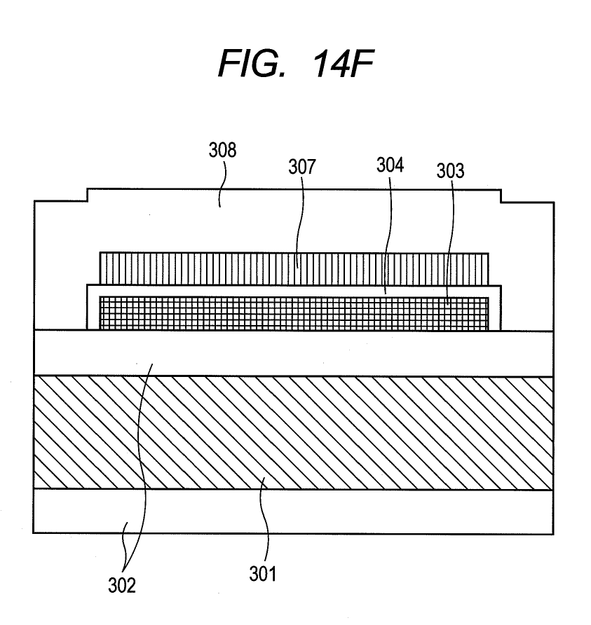

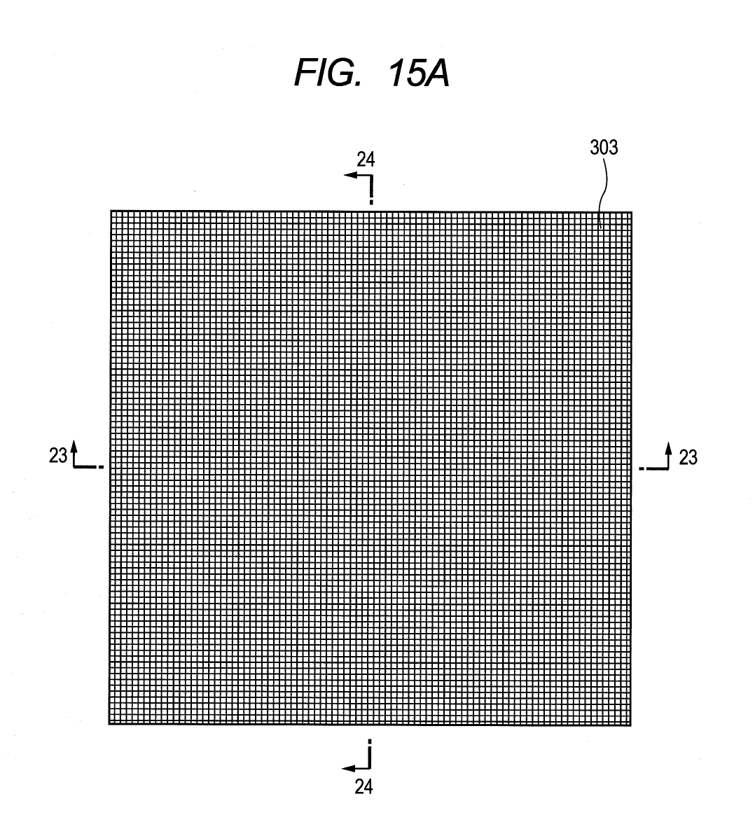

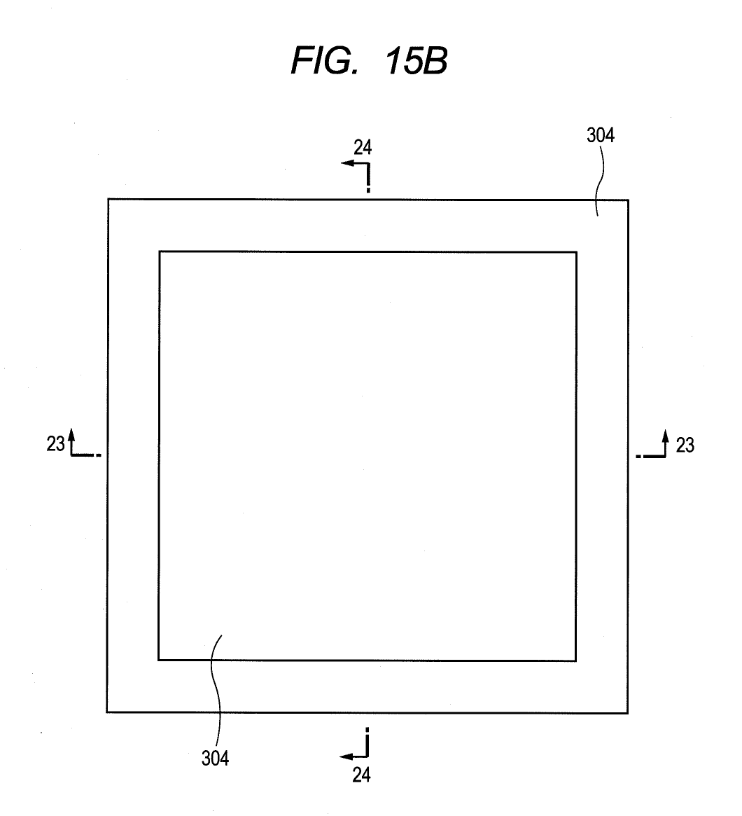

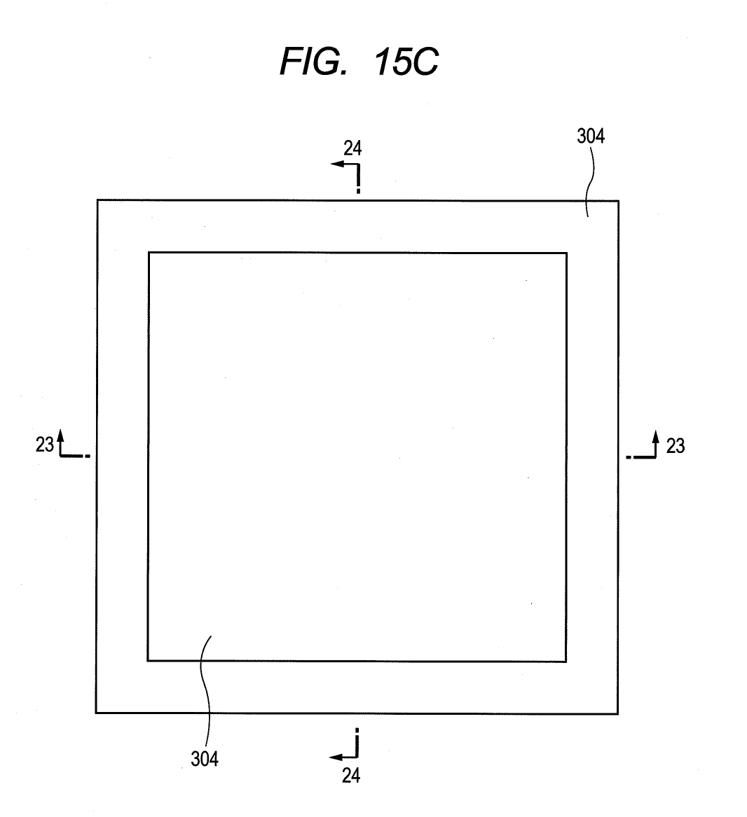

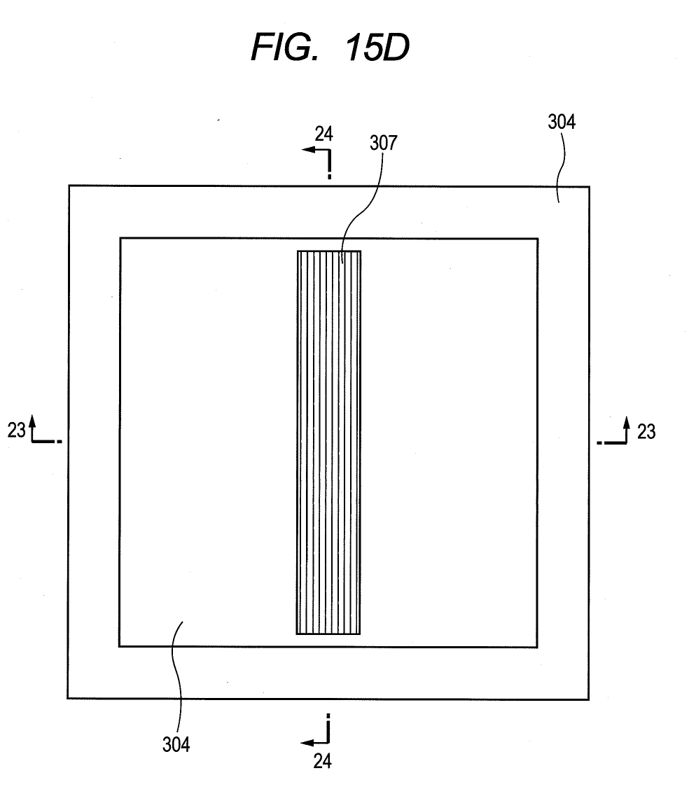

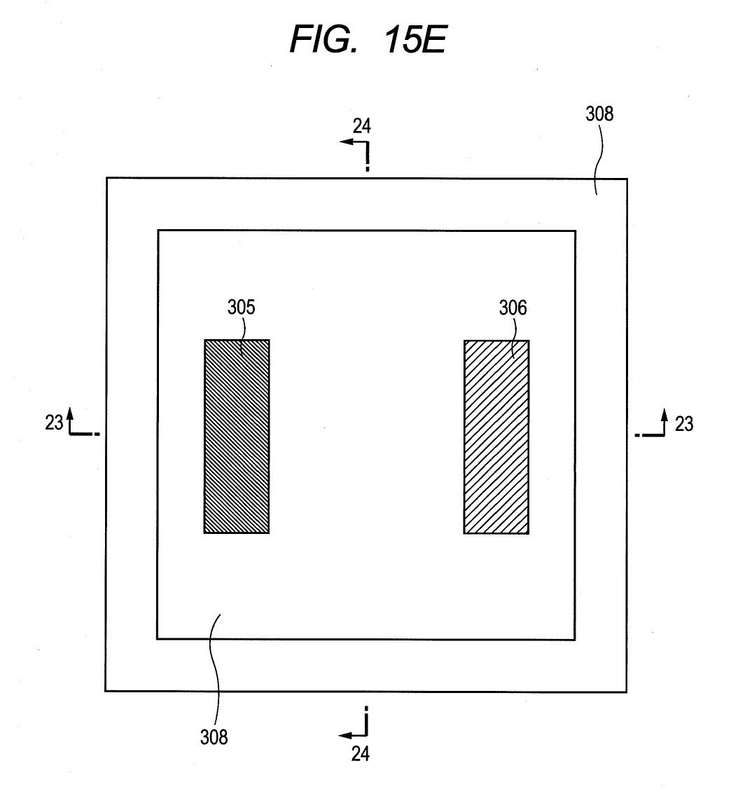

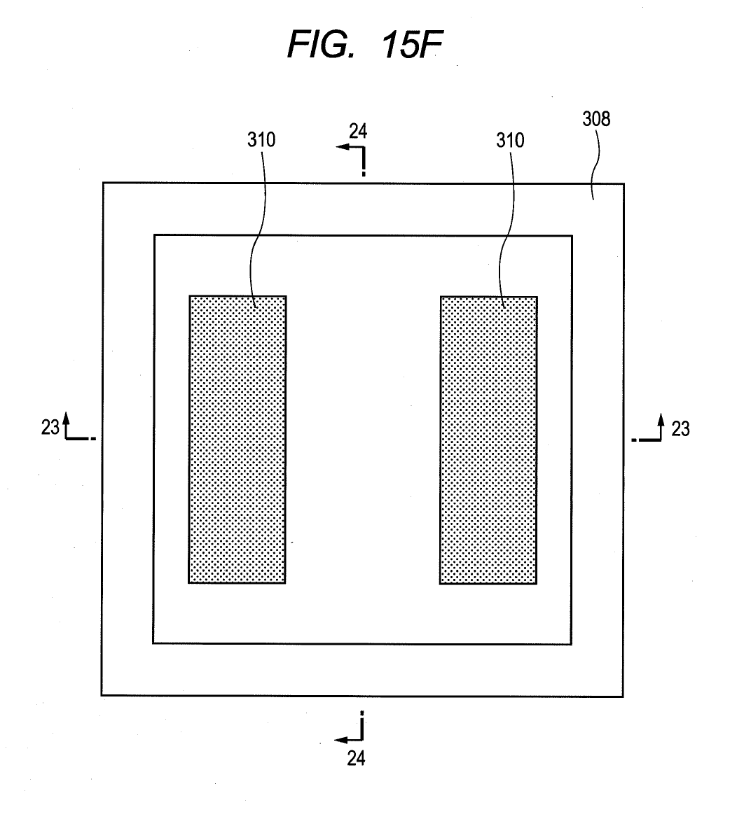

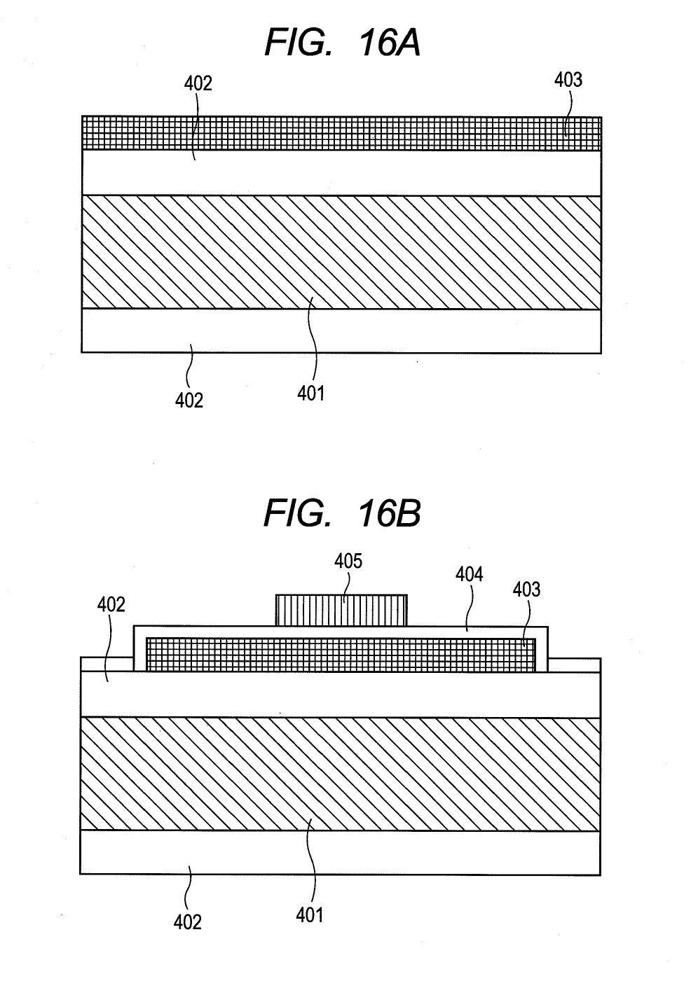

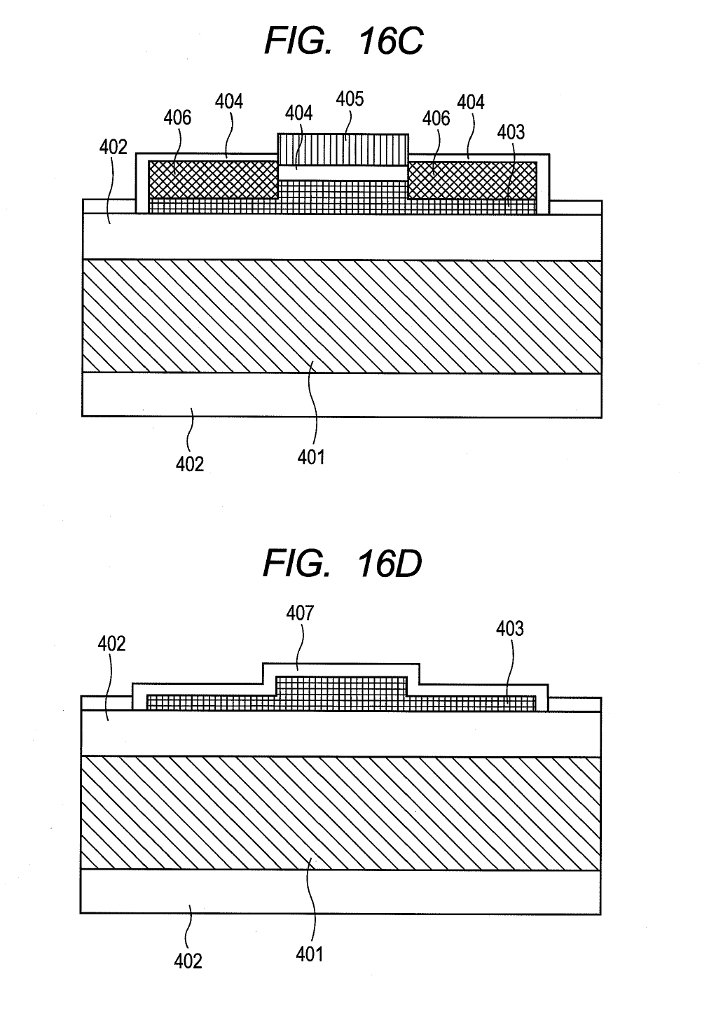

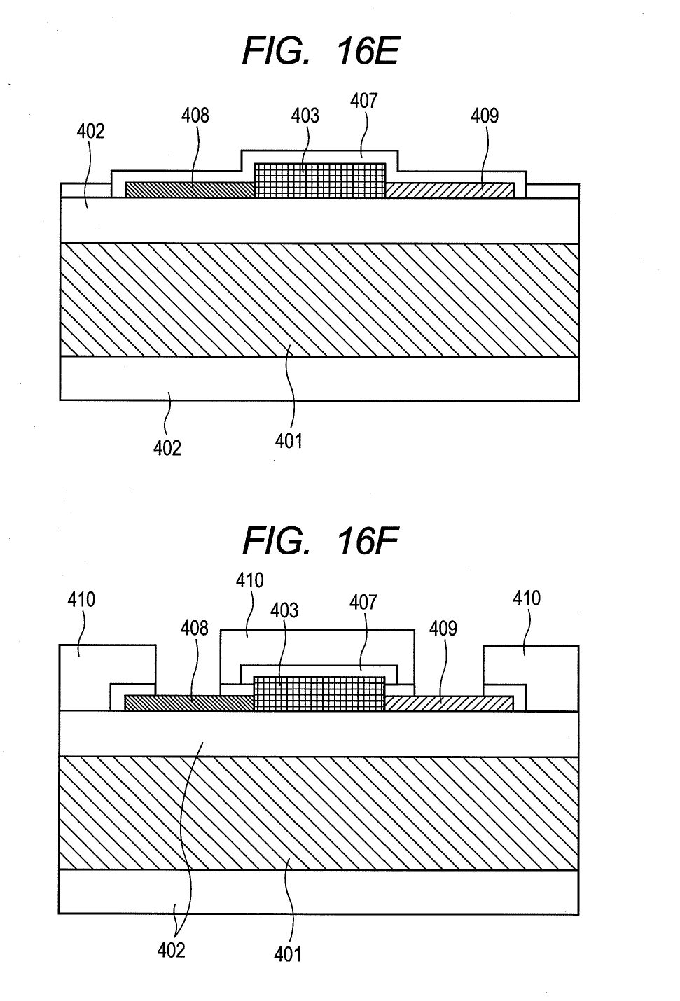

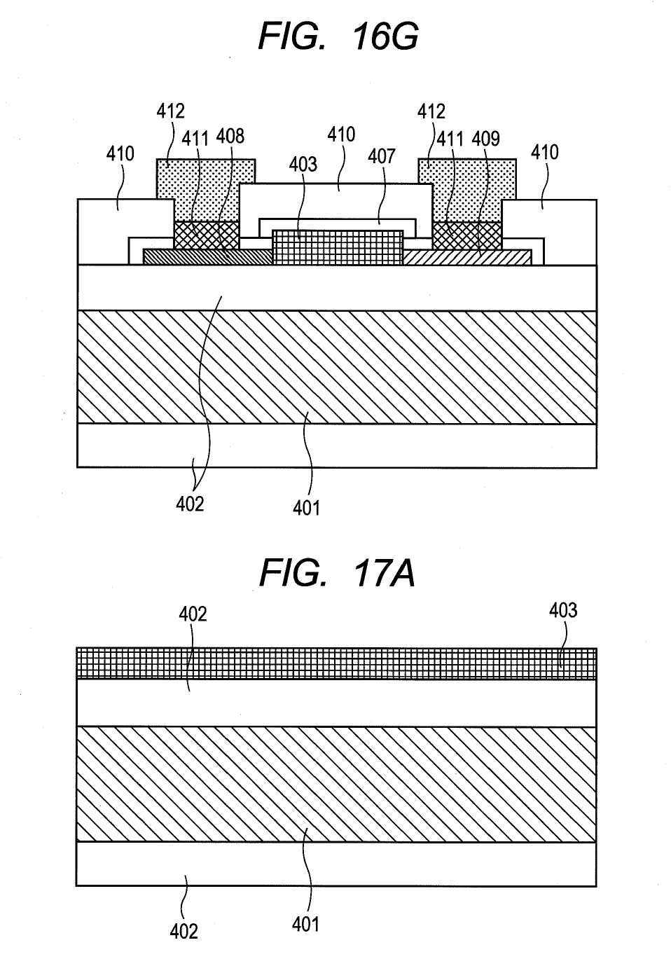

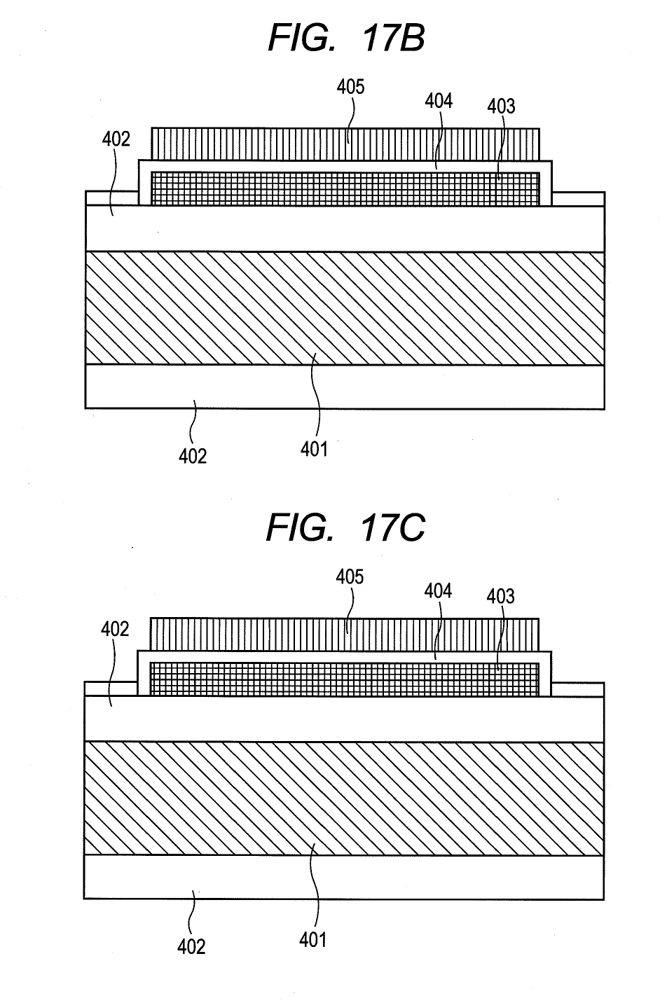

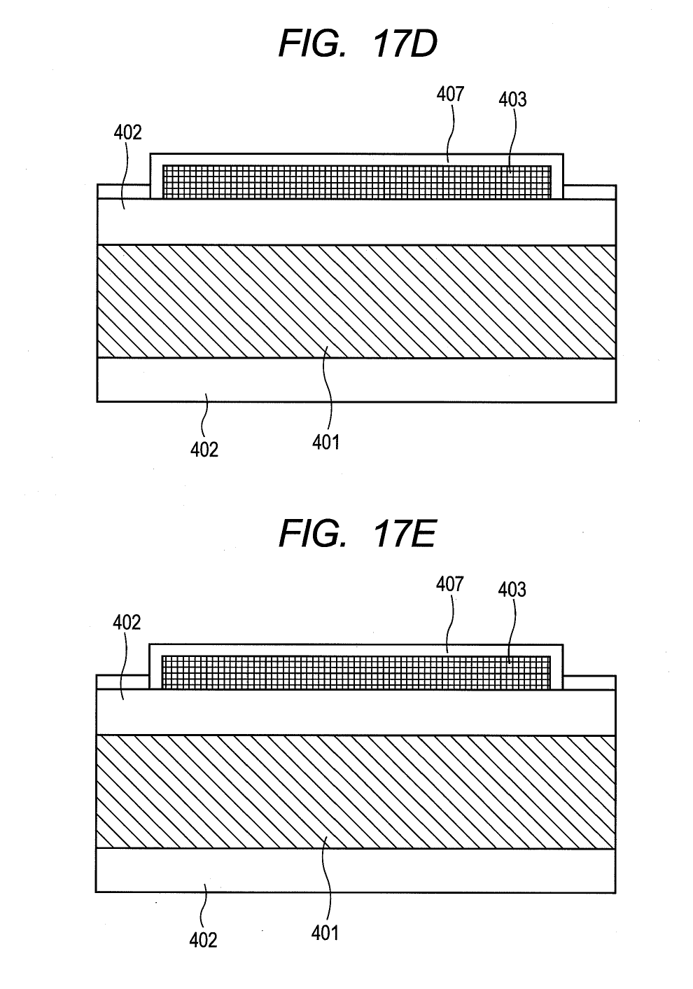

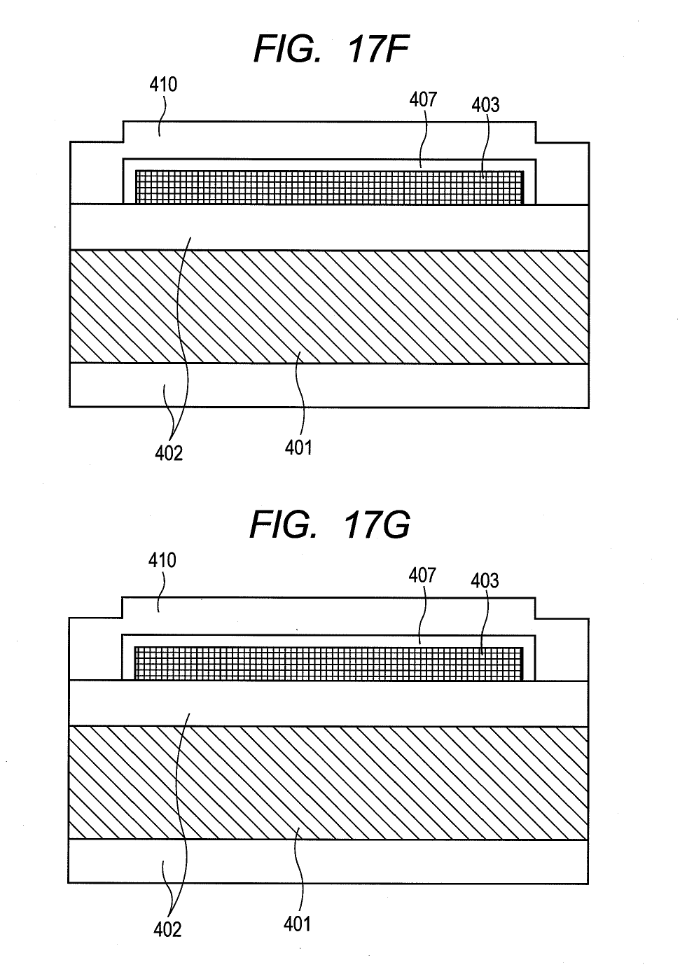

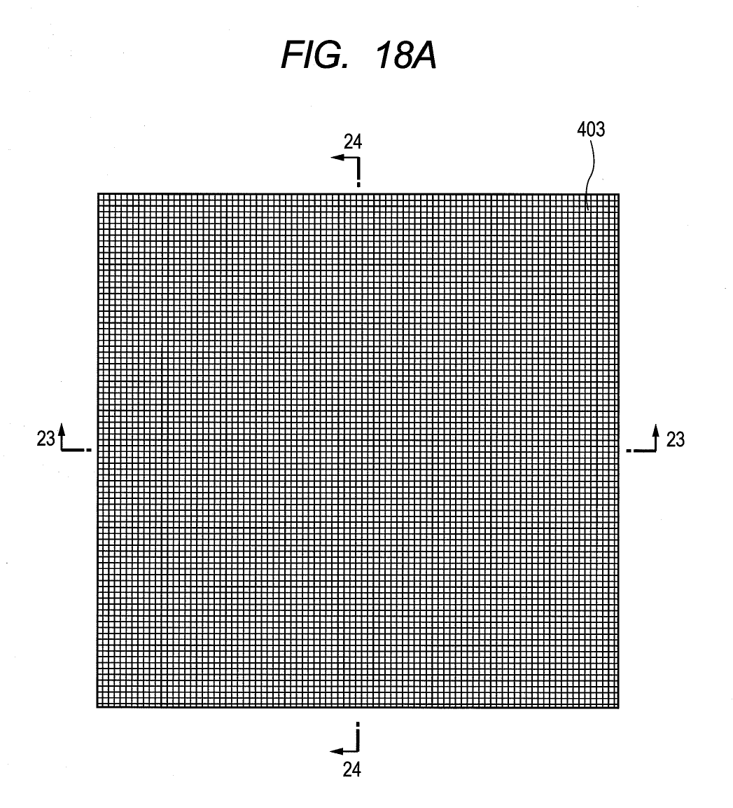

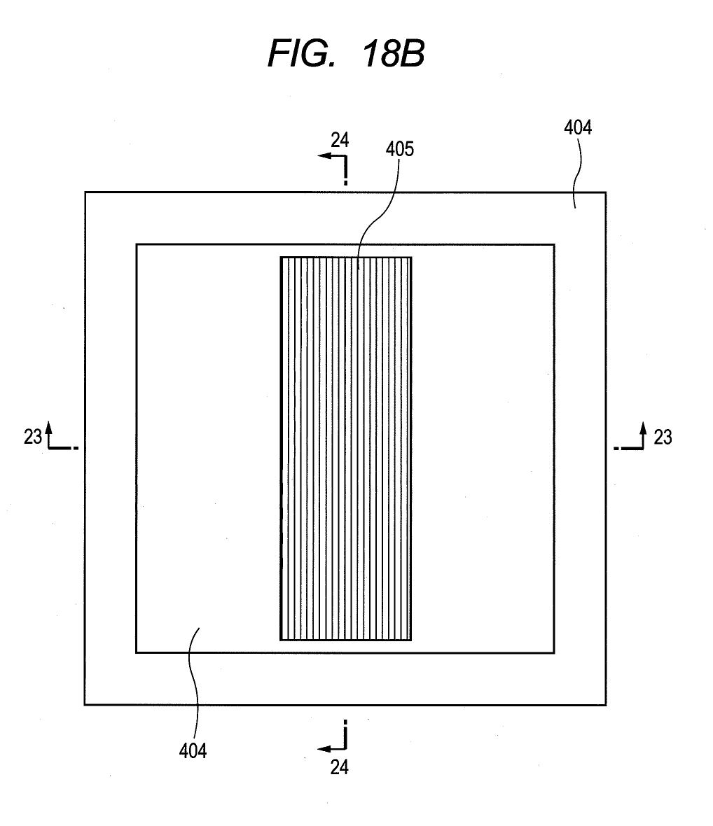

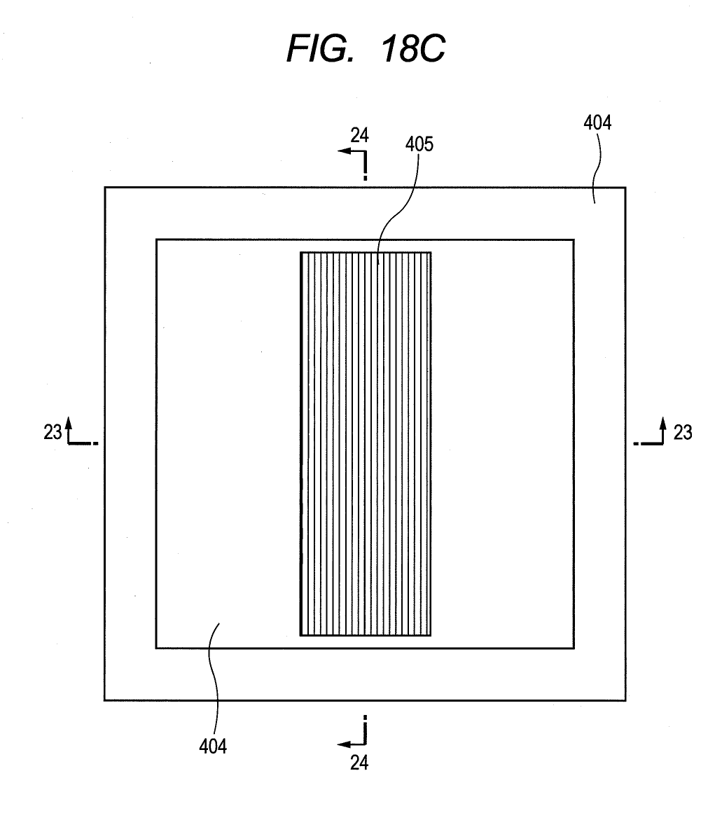

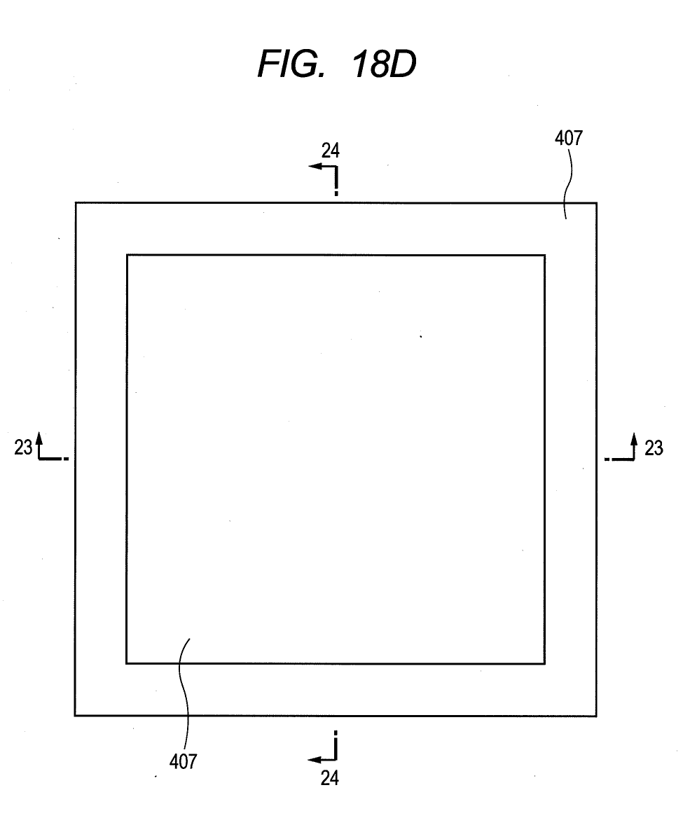

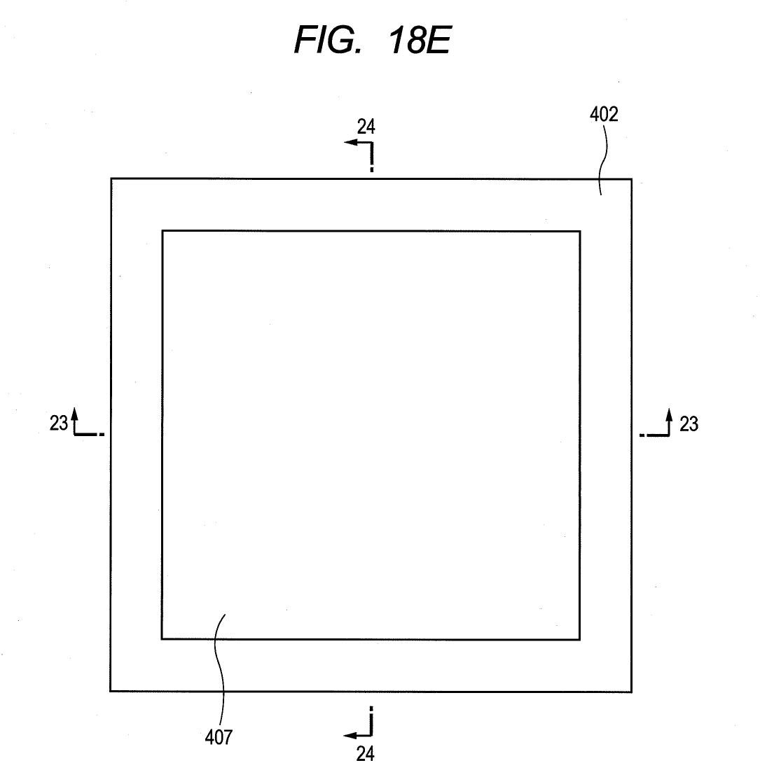

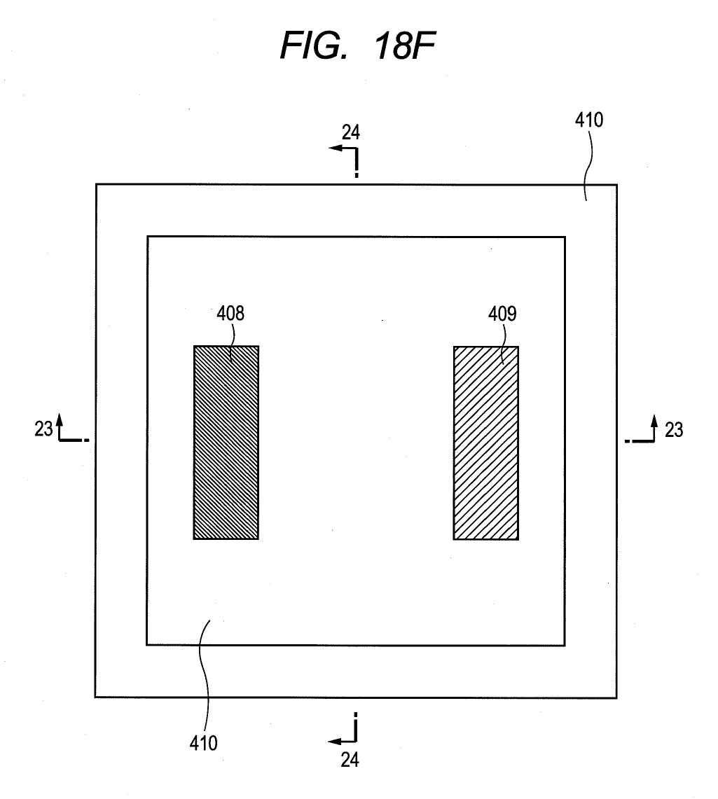

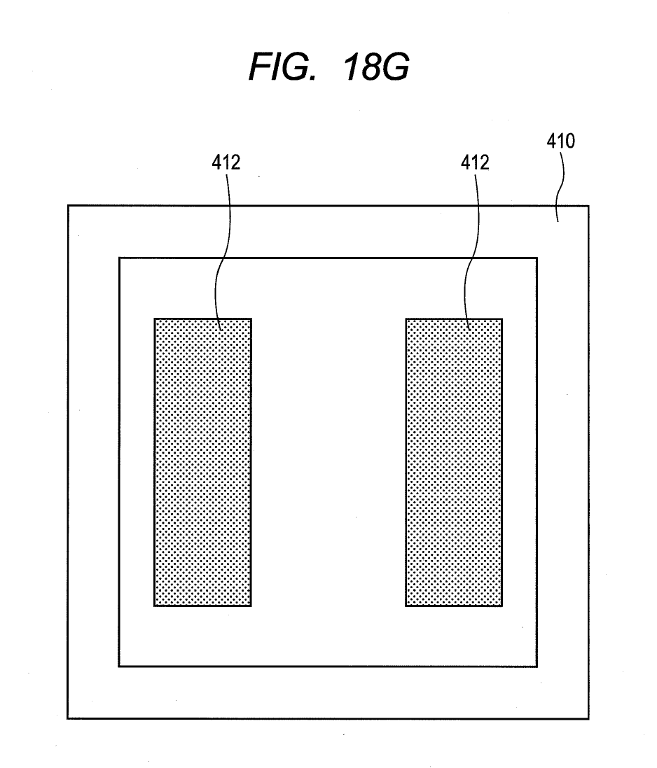

### BRIEF DESCRIPTION OF DRAWINGS

[FIG. 1A] is a step cross sectional view in a step of manufacturing a germanium laser diode according to a first embodiment.

[FIG. 1B] is a step cross sectional view in the step of manufacturing the germanium laser diode according to the first embodiment.

[FIG. 1D] is a step cross sectional view in the step of manufacturing the germanium laser diode according to the first embodiment.

[FIG. 1D] is a step cross sectional view in the step of manufacturing the germanium laser diode according to the first embodiment.

[FIG. 1E] is a step cross sectional view in the step of manufacturing the germanium laser diode according to the first embodiment.

[FIG. 1F] is a step cross sectional view in the step of manufacturing the germanium laser diode according to the first embodiment.

[FIG. 1G] is a step cross sectional view in the step of manufacturing the germanium laser diode according to the first embodiment.

[FIG. 1H] is a step cross sectional view in the step of manufacturing the germanium laser diode according to the first embodiment.

[FIG. 2A] is a step cross sectional view in a step of manufacturing a germanium laser diode according to the first embodiment.

[FIG. 2B] is a step cross sectional view in the step of manufacturing the germanium laser diode according to the first embodiment.

[FIG. 2C] is a step cross sectional view in the step of manufacturing the germanium laser diode according to the first embodiment.

[FIG. 2D] is a step cross sectional view in the step of manufacturing the germanium laser diode according to the first embodiment.

[FIG. 2E] is a step cross sectional view in the step of manufacturing a germanium laser diode according to the first embodiment.

[FIG. 2F] is a step cross sectional view in the step of manufacturing the germanium laser diode according to the first embodiment.

[FIG. 2G] is a step cross sectional view in the step of manufacturing the germanium laser diode according to the first embodiment.

[FIG. 2H] is a step cross sectional view in the step of manufacturing the germanium laser diode according to the first embodiment.

[FIG. 3A] is a step plan view in a step of manufacturing a germanium laser diode according to the first embodiment.

[FIG. 3B] is a step plan view in the step of manufacturing the germanium laser diode according to the first embodiment.

[FIG. 3C] is a step plan view in the step of manufacturing the germanium laser diode according to the first embodiment.

[FIG. 3D] is a step plan view in the step of manufacturing the germanium laser diode according to the first embodiment.

[FIG. 3E] is a step plan view in the step of manufacturing the germanium laser diode according to the first embodiment.

[FIG. 3F] is a step plan view in the step of manufacturing the germanium laser diode according to the first embodiment.

[FIG. 3G] is a step plan view in the step of manufacturing the germanium laser diode according to the first embodiment.

[FIG. 3H] is a step plan view in the step of manufacturing the germanium laser diode according to the first embodiment.

[FIG. 4A] is a step cross sectional view in a step of manufacturing a germanium laser diode according to a second embodiment.

[FIG. 4B] is a step cross sectional view in the step of manufacturing the germanium laser diode according to the second embodiment.

[FIG. 4C] is a step cross sectional view in the step of manufacturing the germanium laser diode according to the second embodiment.

[FIG. 4D] is a step cross sectional view in the step of manufacturing the germanium laser diode according to the second embodiment.

[FIG. 5A] is a step cross sectional view in a step of manufacturing a germanium laser diode according to a second embodiment.

[FIG. 5B] is a step cross sectional view in the step of manufacturing the germanium laser diode according to the second embodiment.

[FIG. 5C] is a step cross sectional view in the step of manufacturing the germanium laser diode according to the second embodiment.

[FIG. 5D] is a step cross sectional view in the step of manufacturing the germanium laser diode according to the second, embodiment.

[FIG. 6A] is a step plan view in a step of manufacturing a germanium laser diode according to the second embodiment.

[FIG. 6B] is a step plan view in the step of manufacturing the germanium laser diode according to the second embodiment.

[FIG. 6C] is a step plan view in the step of manufacturing the germanium laser diode according to the second embodiment.

[FIG. 6D] is a step plan view in the step of manufacturing the germanium laser diode according to the second embodiment.

[FIG. 7A] is a step cross sectional view in a step of manufacturing a germanium laser diode according to a third embodiment.

[FIG. 7B] is a step cross sectional view in the step of manufacturing the germanium laser diode according to the third embodiment.

[FIG. 7C] is a step cross sectional view in the step of manufacturing the germanium laser diode according to the third embodiment.

[FIG. 7D] is a step cross sectional view in the step of manufacturing the germanium laser diode according to the third embodiment.

[FIG. 7E] is a step cross sectional view in the step of manufacturing the germanium laser diode according to the third embodiment.

[FIG. 8A] is a-step cross sectional view in a step of manufacturing a germanium laser diode according to the third embodiment.

[FIG. 8B] is a step cross sectional view in the step of manufacturing the germanium laser diode according to the third embodiment.

[FIG. 8C] is a step cross sectional view in the step of manufacturing the germanium laser diode according to the third embodiment.

[FIG. 8D] is a step cross sectional view in the step of manufacturing the germanium laser diode according to the third embodiment.

[FIG. 8E] is a step cross sectional view in the step of manufacturing the germanium laser diode according to the third embodiment.

[FIG. 9A] is a step plan view in a step of manufacturing a germanium laser diode according to the third embodiment.

[FIG. 9B] is a step plan view in the step of manufacturing the germanium laser diode according to the third embodiment.

[FIG. 9C] is a step plan view in the step of manufacturing the germanium laser diode according to the third embodiment.

[FIG. 9D] is a step plan view in the step of manufacturing the germanium laser diode according to the third embodiment.

[FIG. 9E] is a step plan view in the step of manufacturing the germanium laser diode according to the third embodiment.

[FIG. 10A] is a step cross sectional view in a step of manufacturing a germanium laser diode according to a fourth embodiment.

[FIG. 10B] is a step cross sectional view in the step of manufacturing the germanium laser diode according to the fourth embodiment.

[FIG. 11A] is a step cross sectional view in the step of manufacturing the germanium laser diode according to the fourth embodiment.

[FIG. 11B] is a step cross sectional view in the step of, manufacturing the germanium laser diode according to the fourth embodiment.

[FIG. 12A] is a step cross sectional view in a step of manufacturing a germanium laser diode according to the fourth embodiment.

[FIG. 12B] is a step cross sectional view in the step of manufacturing the germanium laser diode according to the fourth embodiment.

[FIG. 13A] is a step cross sectional view in a step of manufacturing a germanium laser diode according to a fifth embodiment.

[FIG. 13B] is a step cross sectional view in the step of manufacturing the germanium laser diode according to the fifth embodiment.

[FIG. 13C] is a step cross sectional view in the step of manufacturing the germanium laser diode according to the fifth embodiment.

[FIG. 13D] is a step cross sectional view in the step of manufacturing the germanium laser diode according to the fifth embodiment.

[FIG. 13E] is a step cross sectional view in the step of manufacturing the germanium laser diode according to the fifth embodiment.

[FIG. 13F] is a step cross sectional view in the step of manufacturing the germanium laser diode according to the fifth embodiment.

[FIG. 14A] is a step cross sectional view in a step of manufacturing a germanium laser diode according to the fifth embodiment.

[FIG. 14B] is a step cross sectional view in the step of manufacturing the germanium laser diode according to the fifth embodiment.

[FIG. 14C] is a step cross sectional view in the step of manufacturing the germanium laser diode according to the fifth embodiment.

[FIG. 14D] is a step cross sectional view in the step of manufacturing the germanium laser diode according to the fifth embodiment.

[FIG. 14E] is a step cross sectional view in the step of manufacturing the germanium laser diode according to the fifth embodiment.

[FIG. 14F] is a step cross sectional view in the step of manufacturing the germanium laser diode according to the fifth embodiment.

[FIG. 15A] is a step plan view in a step of manufacturing a germanium laser diode according to the fifth embodiment.

[FIG. 15B] is a step plan view in the step of manufacturing the germanium laser diode according to the fifth embodiment.

[FIG. 15C] is a step plan view in the step of manufacturing the germanium laser diode according to the fifth embodiment.

[FIG. 15D] is a step plan view in the step of manufacturing the germanium laser diode according to the fifth embodiment.

[FIG. 15E] is a step plan view in the step of manufacturing the germanium laser diode according to the fifth embodiment.

[FIG. 15F] is a step plan view in the step of manufacturing the germanium laser diode according to the fifth embodiment.

[FIG. 16A] is a step cross sectional view in a step of manufacturing a germanium laser diode according to a sixth embodiment.

[FIG. 16B] is a step cross sectional view in the step of manufacturing the germanium laser diode according to the sixth embodiment.

[FIG. 16C] is a step cross sectional view in the step of manufacturing the germanium laser diode according to the sixth embodiment.

[FIG. 16D] is a step cross sectional view in the step of manufacturing the germanium laser diode according to the sixth embodiment.

[FIG. 16E] is a step cross sectional view in the step of manufacturing the germanium laser diode according to the sixth embodiment.

[FIG. 16F] is a step cross sectional view in the step of manufacturing the germanium laser diode according to the sixth embodiment.

[FIG. 16G] is a step cross sectional view in the step of manufacturing the germanium laser diode according to the sixth embodiment.

[FIG. 17A] is a step cross sectional view in a step of manufacturing a germanium laser diode according to the sixth embodiment.

[FIG. 17B] is a step cross sectional view in the step of manufacturing the germanium laser diode according to the sixth embodiment.

[FIG. 17C] is a step cross sectional view in the step of manufacturing the germanium laser diode according to the sixth embodiment.

[FIG. 17D] is a step cross sectional view in the step of manufacturing the germanium laser diode according to the sixth embodiment.

[FIG. 17E] is a step cross sectional view in the step of manufacturing the germanium laser diode according to the sixth embodiment.

[FIG. 17F] is a step cross sectional view in the step of manufacturing the germanium laser diode according to the sixth embodiment.

[FIG. 17G] is a step cross sectional view in the step of manufacturing the germanium laser diode according to the sixth embodiment.

[FIG. 18A] is a step plan view in a step of manufacturing a germanium laser diode according to the sixth embodiment.

[FIG. 18B] is a step plan view in the step of manufacturing the germanium laser diode according to the sixth embodiment.

[FIG. 18C] is a step plan view in the step of manufacturing the germanium laser diode according to the sixth embodiment.

[FIG. 18D] is a step plan view in the step of manufacturing the germanium laser diode according to the sixth embodiment.

[FIG. 18E] is a step plan view in the step of manufacturing a germanium laser diode according to the sixth embodiment.

[FIG. 18F] is a step plan view in a step of manufacturing the germanium laser diode according to the sixth embodiment.

[FIG. 18G] is a step plan view in the step of manufacturing the germanium laser diode according to the sixth embodiment.

### DESCRIPTION OF EMBODIMENTS

### (Mode for Practicing the Invention)

Embodiments are to be described specifically with reference to the drawings.

### First Embodiment

This embodiment discloses a Fabry-Perot type (simply referred to as FP) germanium laser diode prepared by a method capable of easily forming by using a usual silicon process, as well as a manufacturing method thereof.

FIG. 1A to FIG. 1H and FIG. 2A to FIG. 2H show cross sectional structures in the order of manufacturing steps. Further, FIG. 3A to FIG. 3H show plan views as viewed from above in the order of manufacturing steps.

The cross sectional views of FIG. 1A to FIG. 1H and FIG. 2A to FIG. 2H show structures cut along cross sections 23 and 24 in FIG. 3A to FIG. 3H, respectively.

Cross sectional views of FIG. 1H and FIG. 2H are views for completed devices in this embodiment cut out at positions shown by cut-out lines 23, 24 in FIG. 3H respectively.

The manufacturing steps are to be described sequentially.

At first, as shown in FIG. 1A, FIG. 2A, and FIG. 3A, a GOI substrate in which a silicon substrate 1 as a support substrate, a silicon dioxide 2 and a Germanium On Insulator (hereinafter simply referred to as GOI) 3 as a Buried Oxide (hereinafter simply referred to as BOX) film were laminated was prepared.

The GOI substrate may also be prepared by using a step of preparing germanium over BOX by epitaxially growing silicon-germanium under the condition of not generating threading dislocation over the Silicon On Insulator and then selectively oxidizing only silicon.

The initial film thickness of the GOI 3 before the process manufactured trially in this embodiment was 100 nm. Further, the film thickness of the silicon dioxide 2 was 1000 nm.

As apparent from FIGS. 1A to 3A, the silicon dioxide 2 was formed also over the rear face of the silicon substrate 1. This is for preventing warp of the wafer of the silicon substrate 1.

Since the silicon dioxide 2 as thick as 1000 nm is formed, a strong compressive stresses is applied to the silicon substrate 1 and it is devised such that the wafer does not warp as a whole by forming the film over the surface and the rear face each by an identical thickness. It is necessary to take care so that also the silicon dioxide 2 over the rear face is not eliminated during the process. If the silicon dioxide 2 at the rear face is eliminated in the process of cleaning or wet etching, the entire wafer warps, so that the wafer is not adsorbed to an electrostatic chuck and the subsequent manufacturing process cannot possibly be performed.

Then, a silicon dioxide 4 was deposited over the surface by using Chemical Vapor Deposition (hereinafter simply referred to as CVD) or like other device.

Then, after coating a resist and leaving the resist only in a desired region by mask exposure using photolithography, the silicon dioxide 4 was fabricated by applying wet etching into a state shown in FIG. 1B, FIG. 2B and FIG. 3B. For the fabrication method, dry etching may also be used.

Successively, after cleaning the surface by an appropriate cleaning step, germanium 5 doped to a p-type state at high concentration was epitaxially grown over the GOI 3 selectively only in the opening portion to form a state shown in FIG. 1C, FIG. 2C, and FIG. 3C. The germanium 5 serves as an electrode for injecting holes after completion of the device.

As a method of doping the p-type impurity, ion implantation may also be used. Although device isolation is not illustrated in this embodiment, device isolation can be performed by using, for example, a step of fabricating the GOI3 into a mesa shape or a Shallow Trench Isolation (STI), a Local Oxidation of Silicon (LOCOS) step or the like.

Then, a silicon dioxide 6 is deposited over the surface by using CVD or like other device. Successively, after coating a resist and leaving the resist only in a desired region by mask exposure using photolithography, the silicon oxide 4 is fabricated by applying wet etching into a state shown in FIG. 1D, FIG. 2D and FIG. 3D. For the fabrication method, drying etching may also be used.

Subsequently, after cleaning the surface by an appropriate cleaning step, a germanium 7 at an impurity concentration of 1×1¹⁸/cm³ or less was epitaxially grown by 200 nm over the p-type germanium selectively only in the opening portion to form a state shown in FIG. 1E, FIG. 2E, and FIG. 3E.

In this process, the threading dislocation in the germanium 7 was 1×10⁶/cm² or less. Since the germanium 7 serves as a light-emitting layer after completion of the device, it should be prepared with utmost care so that threading dislocation does not intrude.

Silicon or silicon-germanium may also be epitaxially grown as a cap layer succeeding to the epitaxial growing of the germanium 7. When silicon-germanium is used for the cap layer, it also has a function of moderating the strain caused by lattice constant between an n-type silicon electrode deposited subsequently and the germanium 7 as the light-emitting layer.

Further, since the germanium 7 also serves as an optical confinement layer after completion of the device, the germanium 7 is designed in this embodiment so as to form an optical resonator in the shape of a fine line.

Successively, after depositing a silicon 8 doped with an impurity into an n-type state at high concentration over the entire surface by CVD or like other apparatus, coating a resist and then leaving the resist only in a desired region by mask exposure using photolithography, the n-type silicon 8 is fabricated by applying anisotropic dry etching into a state shown in FIG. 1F, FIG. 2F, and FIG. 3F. The n-type silicon 8 serves as an electrode for injecting holes after completion of the device.

As the method of doping the impurity into the n-type silicon 8, ion implantation may also be used.

Further, since silicon has a refractive index smaller than that of the germanium 7 as the optical confinement layer, light can be confined effectively in the optical confinement layer. Actually, 80% or more of a confinement coefficient can be attained for the light guided in the resonator and the germanium 7. This is outstandingly large when compared-with the confinement coefficient of about several % obtained in a case of using a germanium quantum well. In addition, since silicon is used as the n-type electrode, the effect of free carrier absorption by the electrode can be suppressed.

As the n-type electrode, silicon-germanium may also be used.

When the germanium 7 has a facet depending on the epitaxial growing condition of the germanium 7, the n-type silicon 8 may also be deposited after performing passivation by silicon dioxide, etc. after epitaxial growing of the germanium 7 and opening the germanium 7 by resist patterning.

Then, a silicon dioxide 9 was deposited over the surface by using CVD or like other apparatus. Successively, after coating a resist and leaving the resist only in a desired region by mask exposure using photolithography, the silicon dioxide 9 was fabricated by applying wet etching into a state shown in FIG. 1G, FIG. 2G, and FIG. 3G to form an opening for the portion of a p-type electrode and an n-type electrode.

In this case, since the etching selectivity is sufficiently high between the silicon dioxide and the electrode, the opening can be formed with no problem even when a step is present between the n-type electrode and the p-type electrode.

Successively, after depositing TiN and Al over the entire surface, coating a resist and then leaving the resist only in a desired region by mask exposure using photolithography, Al was wet etched and then TiN was etched to pattern the TiN electrode 10 and the Al electrode 11 as a result.

As the method of patterning, dry etching may also be used.

Successively, a hydrogen annealing process was applied to perform a process of terminating defects generated during the process into a state shown in FIG. 1H, FIG. 2H, and FIG. 3H to complete the device.

The configuration and the operation characteristics of the completed device prepared as described above, that is, a germanium-laser are to be described.

At first, in FIG. 1H, a germanium light-emitting layer 7 is formed between the p-type electrode 5 and an n-type electrode 8. Since threading dislocation present in the germanium light-emitting layer 7 is. 1×10⁶/cm² or less, fewer carrier traps are derived from crystal defects and high current can be applied.

The germanium light-emitting layer 7 is fabricated into the shape of a fine line and it also serves as a Fabry-Perot type resonator.

By flowing a current in the forward direction between the p-type electrode 5 and then-type electrode 8, carriers were injected at high concentration into the germanium light-emitting layer 7, and electrons and holes were recombined to emit light. The emitted light was intensely confined in the germanium light emitting layer 7 and, when a current higher than a threshold value was supplied, stimulated emission was induced to generate laser oscillation. The oscillation wavelength in this case was at about 1500 nm, which was substantially identical with the designed wavelength. No strong strain was applied on the light-emitting layer and germanium emitted light at an inherent band gap energy.

Further, since the laser light was emitted parallel to the silicon substrate 1, it was also demonstrated that this is optimal to the application use such as optical on-chip interconnect.

By the way, in FIG. 1H, FIG. 2H, and FIG. 3H described above, while steps up to the interconnect step and cross sectional structures are shown, when an optical integrated circuit is formed, a desired interconnection process may be applied subsequently.

Further, when this is hybridized with an electronic circuit, several of the steps described above can be performed simultaneously with a step of forming transistors. When an optical device is prepared by way of a usual silicon process, the device can be easily hybridized with an electronic device.

Particularly, since the germanium laser diode according to the invention can oscillate at about 1500 nm with less transmission loss of optical fiber, it has been found that a laser of high reliability and at low cost can be provided while utilizing existent infrastructures for optical communication as they are.

### Second Embodiment

This embodiment discloses a Distributed Bragg Reflector (hereinafter simply referred to as DBR) type germanium laser diode that can be formed easily by using a usual silicon process, and a manufacturing method thereof. FIG. 1A to FIG. 1F, FIG. 4A to FIG. 4D, and FIG. 2A to FIG. 2F, and FIG. 5A to FIG. 5D show cross sectional structures in the order of the manufacturing steps. Further, FIG. 3A to FIG. 3F and FIG. 6A to FIG. 6D show plan views as viewed-from above in the order of the manufacturing steps.

Cross sectional views of FIG. 1A to FIG. 1F to FIG. 2A to FIG. 2F show structures cut out along cross sections 23 and 24 in FIG. 3A to FIG. 3F respectively. Further, cross sectional views of FIG. 4A to FIG. 4D and FIG. 5A to FIG. 5D show structures cut out along cross sections 23 and 24 in FIG. 6A to. FIG. 6D, respectively.

Cross sectional views of FIG. 4D and FIG. 5D are views of a completed device in this embodiment cut out along positions shown by cut out lines 23 and 24 in FIG. 6D respectively.

The manufacturing steps are to be described sequentially. Since the manufacturing steps in FIG. 1A to FIG. 1F, FIG. 2A to FIG. 2F, FIG. 3A to FIG. 3F are identical with those of the first embodiment, they are not described.

At first, a silicon dioxide 9 is deposited over the surface from the state shown in FIG. 1F, FIG. 2F, and FIG. 3F by using CVD or like other apparatus.

Successively, after coating a resist, and leaving the resist only in a desired region by mask exposure using photolithography, the silicon dioxide 9 was fabricated by applying anisotropic dry etching into a state shown in FIG. 4A, FIG. 5A, and FIG. 6A.

Successively, after depositing amorphous silicon over the entire surface and leaving a resist only in the desired region by resist patterning using photolithography, amorphous silicon was fabricated by using anisotropic dry etching. In this case, small pieces of amorphous silicon were formed periodically as a DVR mirror 101 on both ends of the germanium light-emitting layer 7 into a state shown in FIG. 4B, FIG. 5B, and FIG. 6B.

The DER mirror 101 is a dielectric mirror formed due to the difference of a refractive index from that of the peripheral insulating film and a reflectance as high as 99.9% or more can be attained.

Since the mirror at such a high reflectance can be formed simply by the silicon process, laser oscillation can be attained even when the light-emission from germanium is weak.

In the design of the DBR mirror 101, the width and the distance of the small pieces of amorphous silicon are important parameters and designed such that they are a multiple integer of about ½ of an emission wavelength in a medium.

While only three small pieces of amorphous silicon are illustrated for each of the DBR mirrors in FIG. 5B and FIG. 6B, the reflectance can be actually made higher by increasing the number of the small pieces.

In this embodiment, the small pieces were trially manufactured while changing the number of them as 4, 10, 20 and 100 respectively and it was confirmed that the current density at the oscillation threshold value was smaller and the reflectance of the DBR mirror 101 was higher as the number of smaller pieces increased.

Then, a silicon dioxide 102 was deposited over the surface by using CVD or like other apparatus. Successively, after coating a resist and leaving the resist only in a desired region by mask exposure using photolithography, the silicon dioxide was fabricated by applying wet etching into a state shown in FIG. 4C, FIG. 5C, and FIG. 6C to form openings in the portions for a p-type electrode and an n-type electrode.

In this case, since the etching selectivity is sufficiently high between the silicon dioxide and the electrode, openings can be formed with no problem even when a step is present between the n-type electrode and the p-type electrode.

Successively, after depositing TIN and Al over the entire surface, coating a resist, and then leaving the resist only in a desired region by mask exposure using photolithography, Al was wet etched and the TiN was etched to pattern the TiN electrode 10 and the Al electrode 11 as a result.

As the method of patterning, dry etching may also be used.

Successively, a hydrogen annealing process was applied to perform a process for terminating defects generated during the process with hydrogen into a state shown in FIG. 4D, FIG. 5D, and FIG. 6D to complete the device.

The configuration and the operation characteristics of the completed device prepared as-described above, that is, a germanium-laser are to be described.

At first, in FIG. 4D and FIG. 5D, the germanium light-emitting layer 7 is formed between the p-type electrode 5 and the n-type electrode 8. Incidentally, since threading dislocation present in the germanium light-emitting layer 7 is 1×10⁶/cm² or less, fewer carrier traps are derived from crystal defects and high current can be applied. The germanium light-emitting layer 7 is fabricated into the shape of a fine line and it also serves as an optical confinement layer.

DBR mirror 101 comprising amorphous silicon is formed on both ends of the germanium light-emitting layer 7.

By flowing a current in the forward direction between the p-type electrode 5 and the n-type electrode 8, carriers were injected at high concentration into the germanium light-emitting layer 7, and electrons and holes were recombined to emit light. The emitted light was intensely confined in the germanium light-emitting layer 7 and, when a current higher than a threshold value was supplied, stimulated emission was induced to generate laser oscillation.

Since the reflectance at 99.9% or higher was attained by the DBR mirror, loss at the mirror reflection could be decreased. As a result, the threshold current which was 3 mA in the Fabry-Perot type could be decreased to 1 mA. The oscillation wavelength was at about 1500 nm, which was the designed wavelength, and this was a single mode oscillation according to the spectral analysis thereof.

### Third Embodiment

This embodiment discloses a Distributed Feed-Back (hereinafter simply referred to as DFB) type germanium laser diode prepared by a method capable of easily forming by using a usual silicon process, and a manufacturing method thereof. FIG. 1A to FIG. 1C, FIG. 7A to FIG. 7E, and FIG. 2A to FIG. 2C, and FIG. 8A to FIG. 8E show cross sectional structures in the order of manufacturing steps. Further, FIG. 3A to FIG. 3C and FIG. 9A to FIG. 9E show plan views as viewed from above in the order of the manufacturing steps.

Cross sectional views of FIG. 1A to FIG. 1C to FIG. 2A to FIG. 2C show structures cut out along cross sections 23 and 24 in FIG. 3A to FIG. 3C respectively. Further, cross sectional views of FIG. 7A to FIG. 7E and FIG. 8A to FIG. 8E show structures cut out along cross sections 23 and 24 in FIG. 9A to FIG. 9E respectively.

Cross sectional views of FIG. 7E and FIG. 8E are views of a completed device in this embodiment cut out at positions shown by cut out lines 23 and 24 in FIG. 9E respectively.

Manufacturing steps are to be described sequentially. Since the manufacturing steps in FIG. 1A to FIG. 1C, FIG. 2A to FIG. 2C, FIG. 3A to FIG. 3C are identical with those of the first embodiment, they are not described.

At first, a silicon dioxide 6 is deposited by using CVD or like other apparatus over the surface from the state shown in FIG. 1C, FIG. 2C, and FIG. 3C.

Successively, after coating a resist and leaving the resist only in a desired region by mask exposure using photolithography, a silicon dioxide 4 was fabricated by applying anisotropic dry etching into a state shown in FIG. 7A, FIG. 8A, and FIG. 9A.

Subsequently, after cleaning the surface by an appropriate cleaning step, a germanium 7 at an impurity concentration of 1×10¹⁸/cm³ or less was epitaxially grown over the p-type germanium selectively only in the opening portion to form a state shown in FIG. 7B, FIG. 8B, and FIG. 9B. In this process, the threading dislocation in the germanium 7 was 1×10⁶/cm² or less. Since the germanium 7 serves as a light-emitting layer after completion of the device, it is necessary to prepare with an utmost care so that threading dislocation does not intrude.

Silicon or silicon-germanium may also be epitaxially grown as a cap layer succeeding to epitaxial'growing of the germanium 7.

When silicon-germanium is used for the cap layer, it also has a function of moderating the strain caused by a lattice constant between an n-type silicon electrode deposited subsequently and the germanium 7 as the light-emitting layer.

Further, in this embodiment, the germanium 7 is periodically disposed as shown in FIG. 8A and FIG. 9A to form a DFB type optical resonator.

The optical resonator formed with the germanium 7 modulates the refractive index to light propagating in the resonator. That is, the refractive index is larger for a portion where small pieces of the germanium 7 are present and the refractive index is smaller for a portion of gap between each of two germanium small pieces.

The lengths of the small pieces of the germanium 7 and the gap therebetween in the waveguide direction are designed respectively such that they are a multiple integer of about ½ wavelength of the emitted light. As a result, the light during propagation in the waveguide channel repeats reflection sensitive to the periodical structure and is intensely confined in the resonator. The DFB type optical resonator was thus formed.

Successively, after depositing a silicon 8 doped with an impurity into as n-type state at high concentration by CVD or like other apparatus over the entire surface, coating a resist, and then leaving the resist only in a desired region by mask exposure using photolithography, an n-type silicon 8 was fabricated by applying anisotropic dry etching into a state shown in FIG. 7C, FIG. 8C, and FIG. 9C.

The n-type silicon 8 serves as an electrode for injecting holes after completion of the device. Further, since silicon has a refractive index smaller than that of the germanium 7 as the optical confinement layer, light can be confined effectively in the optical confinement layer. As the n-type electrode, silicon-germanium may also be used.

When the germanium 7 has a facet depending on the epitaxially growing condition of the germanium 7, the n-type silicon 8 may also be deposited after performing passivation by silicon dioxide, etc. after epitaxial growing of the germanium 7 and opening the germanium 7 by resist patterning.

Then, a silicon dioxide 9 was deposited over the surface by using CVD or like other apparatus. Successively, after coating a resist, and leaving the resist only in a desired region by mask exposure using photolithography, the silicon dioxide 9 was fabricated by applying wet etching into a state shown in FIG. 7D, FIG. 8D, and FIG. 9D to form openings in the portions for the p-type electrode and n-type electrode.

In this case, since the etching selectivity is sufficiently high between the silicon dioxide and the electrode, opening can be formed with no problem even when a step is present between the n-type electrode and the p-type electrode.

Successively, after depositing TiN and Al over the entire surface, coating a resist, and leaving the resist only in a desired region by mask exposure using photolithography, Al was wet etched and then TiN was etched to pattern a TiN electrode 10 and a Al electrode 11 as a result.

As the method of patterning, dry etching may also be used. Successively, a hydrogen annealing process was applied to perform a process for terminating defects generated during the process with hydrogen into a state shown in FIG. 7E, FIG. 8E, and FIG. 9E to complete the device.

The configuration and the operation characteristics of the device completed as described above, that is, germanium laser is to be described.

At first, in FIG. 7E and FIG. 8E, the germanium light-emitting layer 7 is formed between the p-type electrode 5 and the n-type electrode 8. Since threading dislocation present in the germanium light-emitting layer 7 is 1×10⁶/cm² or less, fewer carrier traps are derived from the crystal defects and high current can be applied. The germanium light-emitting layer 7 has a periodical small piece structure and serves also as a DFB type optical resonator.

By flowing a current in the forward direction between the p-type electrode 5 and the n-type electrode 8, carriers were injected at high concentration into the germanium light-emitting layer 7, and electrons and holes were recombined to emit light. The emitted light was intensely confined in the germanium light-emitting layer 7 and, when a current higher than a threshold value was supplied, stimulated emission was induced to generate laser oscillation.

In the laser diode using the DFB mirror of this embodiment, since the DBR mirror was not manufactured but the light-emitting layer was used as the DFB mirror, the manufacturing step could be simplified and carbon foot print could be decreased compared with the laser diode using the DBR mirror. The oscillation wavelength in this case was at about 1500 nm, which was the designed wavelength and this was in a single mode according to spectral analysis thereof.

### Fourth Embodiment

In this embodiment, a germanium laser diode prepared by a method capable of forming easily by using a usual silicon process and applied with tensile strain, and a manufacturing method thereof are disclosed.

While a Fabry-Perot type laser diode illustrated in the drawing was used in this embodiment, the DBR or DFB type laser diode described in the second embodiment and the third embodiment may also be applied.

FIG. 1A to FIG. 1F, FIG. 10A to FIG. 10B, FIG. 2A to FIG. 2F, and FIG. 11A to FIG. 11B show cross sectional structures in the order of manufacturing steps. Further, FIG. 3A to FIG. 3F and FIG. 12A to FIG. 12B show plan views viewed from above in the order of the manufacturing steps.

FIG. 1A to FIG. 1F, FIG. 10A to FIG. 10B, and FIG. 2A to FIG. 2F, and FIG. 11A to FIG. 11B show structures cut out along cross sections 23 and 24 in FIG. 3A to FIG. 3F, and FIG. 12A to FIG. 12B respectively. FIG. 10B, FIG. 11B, and FIG. 12B are views for the completed device in this embodiment.

Cross sectional views of FIG. 1A to FIG. 1F and FIG. 2A to FIG. 2F show structures cut out along cross sections 23 and 24 in FIG. 3A to FIG. 3F respectively. Further, cross sectional views of FIG. 10A to FIG. 10B and FIG. 11A to FIG. 11B respectively show structures cut out along cross sections 23 and 24 in FIG. 12A to FIG. 12B.

Cross sectional views of FIG. 10B and FIG. 11B are views of the completed device in this embodiment cutout at positions shown by cutting lines 23, 24 in FIG. 12B.

The manufacturing steps are to be described sequentially. Since manufacturing steps in FIG. 1A to FIG. 1F, FIG. 2A to FIG. 2F, and FIG. 3A to FIG. 3F are identical with those of the first embodiment, they are not described.

At first, a silicon dioxide 9 was deposited over the surface from the state shown in FIG. 1F, FIG. 2F, and FIG. 3F by using CVD or like other apparatus and, successively, a silicon nitride 201 was deposited only over the surface.

By depositing the silicon nitride 201 only over the surface, tensile strain can be applied to a germanium light-emitting layer 7.

Since the magnitude of tensile strain applied is determined by the film thickens of the silicon nitride 201, the magnitude of the tensile strain to be applied can be controlled by controlling the film thickness of the silicon nitride 201.

Successively, after coating a resist and leaving the resist only in a desired region by mask exposure using photolithography, the silicon nitride 201 was fabricated by anisotropic dry etching and then the silicon dioxide 9 was fabricated successively by applying wet etching into a state shown in FIG. 10A, FIG. 11A, and FIG. 12A to open the portions for the p-type electrode and the n-type electrode.

In this process, since etching selectivity is sufficiently high between the silicon dioxide and the electrode, openings can be formed with no problem even if a step is present between the n-type electrode and the p-type electrode.

Successively, after depositing TiN and Al over the entire surface, coating a resist, and then leaving the resist only in a desired region by mask exposure using photolithography, Al was wet etched and then TiN was etched to pattern a TiN electrode 10 and an Al electrode 11 as a result.

As the method of patterning, dry etching may also be used.

Successively, a hydrogen annealing process was applied to perform a process for terminating defects generated during the process with hydrogen into a state shown in FIG. 10B, FIG. 11B, and FIG. 12B to complete the device.

The configuration and the operation characteristics of the completed device prepared as described above, that is, a germanium-laser are to be described.

At first, in FIG. 10B, a germanium light-emitting layer 7 is formed between a p-type electrode 5 and an n-type electrode 8. Incidentally, since threading dislocation present in the germanium light-emitting layer 7 is 1×10⁶/cm² or less, fewer carrier traps are derived from crystal defects and high current can be applied.

The germanium light-emitting layer 7 is fabricated into the shape of a fine line and it also serves as a Fabry-Perot type optical resonator.

A silicon nitride is formed near the germanium light-emitting layer 7 and has a function of providing tensile strain to the germanium light-emitting layer 7.

By flowing a current in a forward direction between the p-type electrode 5 and the n-type electrode 8, carriers were injected at high concentration into the germanium light-emitting layer 7 and electrons and holes were recombined to emit light. The emitted light was intensely confined in the germanium light-emitting layer 7, and when a current at a threshold value or higher was supplied, stimulated emission was induced to generate laser oscillation. The oscillation wavelength was at about 1550 nm, which was the designed wavelength.

A tensile strain of about 0.3 GPa was applied to the light-emitting layer, the energy difference between the L valley and the Γ valley of the conduction band in the energy band structure was smaller compared with a case of not applying strain, and electrons could be injected at a lower current density to the Γ valley to emit light.

As a result, while the threshold current was 3 mA in the Fabry-Perot type laser diode not applied with strain, the threshold current could be decreased as low as 1 mA.

Since the laser light was emitted parallel to the silicon substrate 1, it was also demonstrated that this was optimal for the application use such as optical on-chip interconnection.

While steps up to the interconnect step and the cross sectional structure thereof are shown in FIG. 10B, FIG. 11B and FIG. 12B described above, when an optical integrated circuit is to be formed, desired interconnect process may be applied subsequently.

Further, when this is hybridized with an electronic circuit, several of the steps described above can be performed simultaneously with a step of forming transistors. When the optical device is prepared by way of a usual silicon process, the device can be easily hybridized with an electronic device.

Particularly, since the germanium laser diode according to the invention can oscillate at about 1550 nm with less transmission loss of optical fiber, it has been found that a laser of high reliability and at low cost can be provided while utilizing existent infrastructures for optical communication as they are.

### Fifth Embodiment

This embodiment discloses a germanium laser diode injected with carriers in a horizontal direction capable of easily forming by using a usual silicon process, and a manufacturing method thereof. FIG. 13A to FIG. 13F, FIG. 14A to FIG. 14F show cross sectional structures in the order of manufacturing steps. Further, FIG. 15A to FIG. 15F show plan views as viewed from above in the order of the manufacturing steps.

Cross sectional views of FIG. 13A to FIG. 13F and FIG. 14A and FIG. 14F show respectively structures cut out along cross sections 23 and 24 in FIG. 15A to FIG. 15F.

Cross sectional views of FIG. 13F and FIG. 14F are views of a completed device in this embodiment cut out at positions shown by cut out lines 23, 24 in FIG. 15F.

Manufacturing steps are to be described sequentially. At first, as shown in FIG. 13A, FIG. 14A, and FIG. 15A, a GOI substrate in which a silicon substrate 301 as a support substrate and a silicon dioxide 302 and, a Germanium On Insulator (hereinafter, simply referred to as GOI) 303 as a Buried Oxide (hereinafter simply referred to as BOX) film are laminated is prepared.

The GOI substrate may also be prepared by using a step of forming germanium over the BOX by epitaxially growing silicon-germanium under the condition of not generating threading dislocation over the Silicon On Insulator and then selectively oxidizing only the silicon.

The initial film thickness of the GOI 303 trially manufactured in this embodiment was 200 nm before process. Further, the film thickness of the silicon dioxide 302 was 1000 nm.

As apparent from FIGS. 13A to 15A, a silicon dioxide 302 is formed also on the rear face of the silicon substrate 301. This is for preventing warp of the wafer of the silicon substrate 301.

Since the silicon dioxide 302 as thick as 1000 nm is formed, a strong compressive stress is applied to the silicon substrate 301 and it is devised such that the wafer does not warp entirely by forming the film on the surface and the rear face each by an identical thickness. It is necessary to take a care so that also the silicon dioxide 302 at the rear face is not eliminated during the process.

If the silicon dioxide 302 at the rear face is eliminated in the process of cleaning or wet etching, the entire wafer warps, so that the wafer is no more adsorbed to an electrostatic chuck and the subsequent manufacturing process cannot possibly be performed.

Then, after coating a resist and leaving the resist only in a desired region by mask exposure using photolithography, the GOI 303 was fabricated into a mesa shape by applying anisotropic dry etching. While only one element is shown in the drawing for simplification, a number of elements can of course be formed over the substrate. Since the silicon process is used, many elements can be integrated at a high yield. By the step, electric isolation between the elements is defined.

Instead of fabricating the GOI 303 into the mesa shape as performed in this embodiment, device isolation may also be performed by using, for example, a Shallow Trench Isolation (STI) step or a Local Oxidation of Silicon (LOCOS) step.

Successively, after applying an appropriate cleaning step, silicon dioxide 304 of 30 nm film thickness was deposited over the surface for protecting the surface by using CVD or like other apparatus into a state shown in FIG. 13B, FIG. 14B, and FIG. 15B. The silicon dioxide 304 serves not only to moderate damages on the substrate by ion implantation introduced in the subsequent process but also to suppress releasing of the impurity into atmospheric air by an activating heat treatment. In this process, the silicon dioxide 304 is formed also on the rear face.

Successively, an impurity is introduced into a desired region in the GOI 303 by ion implantation. Upon implantation of the impurity, after leaving a resist only in a desired region by resist patterning using photolithography, BF₂ ions are ion-implanted at a dose of 1×10¹⁵/cm³ to form a p-type diffusion layer 305 in the GOI 303.

Successively, after removing the resist and leaving the resist only in a desired region by resist patterning attain using photolithography, an n-type diffusion layer electrode 306 was formed in the GOI 303 by ion implantation of P-ions at 1×10¹⁵/cm³. In the ion implantation step, since the GOI 303 is amorphized at a portion where ions are implanted, crystallinity is worsened.

Then, it is important that only the surface of the GOI 303 is amorphized and single crystal germanium remains in a region where the GOI 303 is adjacent to the BOX 302.

When an acceleration voltage for ion implantation is set excessively high, since the GOI 303 is entirely amorphized in the ion-implanted region, this causes a problem that the region does not recover the single crystallinity but forms polycrystals even by applying a subsequent annealing process.

Under the ion implantation condition as defined in this embodiment, since single crystal silicon remains in the region adjacent to the BOX 302, crystallinity can be recovered for example by an activating heat processing after ion implantation. It is extremely important for efficient light-emission that the single crystallinity is good.

Successively, by performing an annealing process in a nitrogen atmosphere the impurity was activated and, at the same time, crystallinity of the GOI 303 was recovered into a state shown in FIG. 13C, FIG. 14C, and FIG. 15C.

Then, a silicon nitride 307 was deposited over the entire surface using CVD or like other apparatus.

Successively, after coating a resist and leaving the resist only in a desired region by mask exposure using photolithography, the silicon nitride 307 was fabricated by applying anisotropic dry etching into a state shown in FIG. 13D, FIG. 14D and FIG. 15D.

The fabricated silicon nitride 307 is disposed above the GOI 303 as a light-emitting layer where the impurity is not doped and has a function of confining light in the light-emitting layer 303 to a direction horizontal to the substrate.

Further, the silicon nitride 307 also has a function of applying tensile strain to the GOI 303 as the light-emitting layer.

In this embodiment, while the silicon nitride is fabricated into the shape of the fine line to prepare a Fabry-Perot type laser diode, a DBR type laser diode can also be manufactured by further disposing small pieces of the silicon nitride periodically also on both ends of the GOI 303 as the light-emitting layer.

Further, a DFB type laser diode can also be manufactured by periodically disposing small pieces of the silicon nitride over the GOI 303 as the-light-emitting layer.

Then, a silicon dioxide 308 was deposited over the surface by using CVD or like other apparatus. Successively, after coating a resist and leaving the resist only in a desired region by mask exposure using photolithography, the silicon dioxide was fabricated by applying wet etching into a state shown in FIG. 13E, FIG. 14E, and FIG. 15E to form openings in the portions for the p-type electrode and the n-type electrode.

Successively, after depositing TiN and Al over the entire surface, coating a resist and then leaving the resist only in a desired region by mask exposure using photolithography, Al was wet etched and then TiN was etched to pattern a TiN electrode 309 and an Al electrode 310 as a result.

As the method of patterning, dry etching may also be used. Successively, a hydrogen annealing process was applied to perform processing of terminating defects generated during the process with hydrogen into a state shown in FIG. 13F, FIG. 14F, and FIG. 15F to complete the device.

The configuration and the operation characteristics of the completed device prepared as described above, that is, a germanium laser is to be described.

At first, in FIG. 13F, the germanium light-emitting layer 303 is formed between the p-type electrode 305 and the n-type electrode 306. Since threading dislocation present in the germanium light-emitting layer 303 is 1×10⁶/cm² or less, fewer carrier traps are derived from the crystal defects and high current can be applied.

The silicon nitride optical resonator is fabricated into the shape of a fine line near the germanium light-emitting layer 303 and has a function as a Fabry-Perot type optical resonator and applies tensile strain to the light-emitting layer.

By supplying a current in a forward direction between the p-type electrode 305 and the n-type electrode 306, carriers were injected at high concentration into the germanium light-emitting layer 303, and electrons and holes, were recombined to emit light. Since substantial change of the refractive index was caused in the horizontal direction by the silicon nitride, the emitted light was intensely confined in the germanium light-emitting layer 303, and when a current at a threshold voltage or higher was supplied, stimulated emission was induced to generate laser oscillation. The oscillation wavelength was at about 1550 nm which was the designed wavelength. Tensile strain of 0.3 GPa was applied to the light-emitting layer, the energy difference between the L valley and the Γ valley of the energy band structure in the germanium light-emitting layer 303 was decreased and carriers were injected to the Γ valley to emit light at a lower current density compared with a case where the strain is not applied.

According to this embodiment, the germanium laser diode can be manufactured without applying a step of epitaxially growing germanium.

Since the laser light is emitted in parallel to the silicon substrate 1, it has also been demonstrated that this is optimal to the use, for example, optical on-chip interconnect.

By the way, in FIG. 13F, FIG. 14F, and FIG. 15F described above, while steps up to the interconnect step and cross sectional structures are shown, when an optical integrated circuit is formed, a desired interconnect process may be applied subsequently.

Further, when this is hybridized with an electronic circuit, several of the steps described above can be performed simultaneously with a step of forming transistors. When the optical device is prepared by way of a usual silicon process, the device can be easily hybridized with an electronic device.

Particularly, since the germanium laser diode according to the invention can oscillate at about 1550 nm with less transmission loss of the optical fiber, it has been found that a laser of high reliability and at low cost can be provided while utilizing existent infrastructures for optical communication as they are.

### Sixth Embodiment

This embodiment discloses a germanium laser diode having a ridged waveguide channel in which carriers are injected in a horizontal direction, and formed easily by using a usual silicon process, and a manufacturing method thereof. FIG. 16A to FIG. 16G, FIG. 17A to FIG. 17G show cross sectional structures in the order of manufacturing steps. Further, FIG. 18A to FIG. 18G show plan views as viewed from above in the order of the manufacturing steps.

Cross sectional views of FIG. 16A to FIG. 16G and FIG. 17A and FIG. 17G show respectively structures cut out along cross sections 23 and 24 in FIG. 18A to FIG. 18G:

Cross sectional views of FIG. 16G and FIG. 17G are views of a completed device in this embodiment cut out along positions shown by cut out lines 23, 24 in FIG. 18G.

The manufacturing steps are to be described sequentially.

At first, as shown in FIG. 16A, FIG. 17A, and FIG. 18A, GOI substrate in which a silicon substrate 401 as a support substrate, a silicon dioxide 402 and a Germanium On Insulator layer (hereinafter simply referred to as GOI) 403 as Buried Oxide (hereinafter simply referred to as BOX) are laminated is prepared.

The GOI substrate may also be prepared by using a step of forming germanium over BOX by epitaxially growing silicon germanium over the Silicon On Insulator under the condition of not generating threading dislocation and then selectively oxidizing only the silicon. The initial film thickness of the GOI 403 trially manufactured in this embodiment before processing was 200 nm. Further, the film thickness of the silicon dioxide 402 was 1000 nm.

As apparent from FIG. 16A, the silicon dioxide 402 is formed also over the rear face of the silicon substrate 401. This is for preventing warp of the wafer of the silicon substrate 401.

Since the silicon dioxide 402 is as thick as 1000 nm is formed, a strong compressive stress is applied to the silicon substrate 401 and it is devised such that the wafer does not warp entirely by forming the film on the surface and the rear face each by an identical thickness. It is necessary to take a care so that also the silicon dioxide 402 at the rear face is not eliminated during the process. If the silicon dioxide 402 on the rear face is eliminated in the process of cleaning or wet etching, the entire wafer warps, so that the wafer is no more adsorbed to an electrostatic chuck and the subsequent manufacturing process may not possibly be performed.

Then, after coating a resist and leaving the resist only in a desired region by mask exposure using photolithography, the GOI 403 was fabricated into a mesa shape by applying anisotropic dry etching. While only one element is shown for the simplification of the drawing, a number of elements can of course be formed over the substrate. Since the silicon process is used, many elements can be integrated at a high yield. By the step, electric isolation between the elements is defined.

Instead of fabricating the GOI 403 into the mesa shape as performed in this embodiment, elements isolation may also be performed by using, for example, a Shallow Trench Isolation (STI) step or a Local Oxidation of Silicon (LOCOS) step.

Successively, after depositing a silicon dioxide 404 as a protective film by CVD or like other apparatus, a silicon nitride 405 was deposited.

Successively, after coating a resist and leaving the resist only in a desired region by mask exposure using photolithography, the silicon nitride 405 was fabricated by applying anisotropic dry etching into a state shown in FIG. 16B, FIG. 17B, and FIG. 18B.

Then, after applying a cleaning step, the GOI 403 was partially oxidized by applying an oxidation process to form a germanium dioxide 406 in a state shown in FIG. 16C, FIG. 17C, and FIG. 18C.

In this case, the oxidation time was controlled such that the film thickness of the GOI was 50 nm at the oxidized portion.

By this step, the GOI 403 was fabricated into a ridged waveguide channel so as to have a function as an optical confinement layer.

Then, after removing the silicon nitride 405 by wet etching using hot phosphoric acid and removing the silicon dioxide 404 and the germanium dioxide 406 by wet etching with hydrofluoric acid, an appropriate cleaning step was applied and a silicon dioxide 407 was deposited as a protective film by CVD or like other apparatus into a state in FIG. 16D, FIG. 17D, and FIG. 18D.

In this embodiment, while the silicon nitride was removed, the silicon nitride may not be removed when it is intended to apply tensile strain to a ridged waveguide channel comprising the GOI 403.

The silicon dioxide 407 serves not only to moderate damages on the substrate by ion implantation introduced by the subsequent process but also suppress releasing of the impurity into atmospheric air by the activating heat treatment.

Successively, an impurity was introduced into a desired region of the GOI 403 by ion implantation. In this case, it is necessary to take care so that the impurity is not implanted into the ridged portion of the GOI 403 in order to prevent absorption of free carriers in the optical confinement layer. Upon implantation of the impurity, after at first leaving a resist only in a desired region by a resist patterning using photolithography, a p-type diffusion layer 408 was formed in the GOI 403 by ion implantation of BF₂ ions at a dose of 1×10¹⁵/cm³ by resist patterning using photolithography.

Successively, after removing a resist and leaving the resist only in a desired region by resist patterning using photolithography again, an n-type diffusion layer electrode 409 was formed in the GOI 403 by ion implantation of P ions at 1×10¹⁵/cm³.

In the ion implantation step, since the ion-implanted portion of the GOI 403 is amorphized, the crystallinity was worsened.

Then, although not illustrated in the drawing, it is important that only the surface of the GOI 403 is amorphized and single crystal germanium remains in a region where the GOI 403 is adjacent with the BOX 402.

If an acceleration voltage of ion implantation is set excessively high, since the ion-implanted region of the GOI 403 is entirely amorphized, this causes a problem that since the region does not recover the single crystallinity but form polycrystals even when subsequent annealing process is applied.

Under the ion implantation conditions as set in this embodiment, since single crystal silicon remains in the region adjacent to the BOX 402, crystallinity can be recovered by an activating heat process, etc. after ion implantation. It is extremely important for efficient light emission that single crystallinity is good.

Subsequently, by performing an annealing process in a nitrogen atmosphere, the impurity was activated and, at the same time, the crystallinity of the GOI 403 was recovered into a state shown in FIG. 16E, FIG. 17E, and FIG. 18E.

Then, a silicon dioxide 410 was deposited as a passivation film by CVD or like other apparatus.

Successively, after coating a resist and leaving the resist only in a desired region by mask exposure using photolithography, silicon dioxide was fabricated by applying wet etching into a state shown in FIG. 16F, FIG. 17F, and FIG. 18F to form openings in the portions for the p-type electrode and the n-type electrode.

Successively, after depositing TiN and Al over the entire surface, coating a resist, and then leaving the resist only in a desired region by mask exposure using photolithography, Al was wet etched and then TiN was etched to pattern a TiN electrode 411 and an Al electrode 412 as a result.

As the method of patterning, dry etching may also be used.

Successively, a hydrogen annealing process was applied to perform processing of terminating defects generated during the process with hydrogen into a state shown in FIG. 16G, FIG. 17G, and FIG. 18G to complete the device.

The configuration and the operation characteristics of the device completed as described above, that is, a germanium-laser is to be described.

At first, in FIG. 16G, the germanium light-emitting layer 403 is formed between the p-type electrode 408 and the n-type electrode 409. Since threading dislocation present in the germanium light-emitting layer 403 is 1×10⁶/cm² or less, fewer carrier traps are derived from the crystal defects and high current can be applied. The germanium light-emitting layer 403 is fabricated into a ridged shape and has a function as a Fabry-Perot type optical resonator.

By supplying a current in a forward direction between the p-type electrode 408 and the n-type electrode 409, carriers were injected at high concentration into the germanium light-emitting layer 403, and electrons and holes were recombined to emit light.

The emitted light was intensely confined in the germanium light-emitting layer 303 of a ridged structure, and when a current at a threshold value or higher was supplied, stimulated emission was induced to generate laser oscillation.

In this embodiment, an intense optical confinement effect was attained by fabricating the light-emitting layer into a ridged shape.

As a result, a threshold current of 10 mA in a laser diode not using the ridge shape could be decreased to 3 mA.

Further, according to this embodiment, the germanium laser diode can be manufactured without applying a step of epitaxially growing germanium. The oscillation wavelength at about 1500 nm was the designed wavelength. No strong strain is applied to the light-emitting layer and the layer emits light at a band gap energy inherent to the generation.

According to this embodiment, the germanium laser diode can be manufactured without applying a step of epitaxially growing germanium.

Since the laser light is emitted in parallel to the silicon substrate 1, it has also been demonstrated that this is optimal to the use, for example, as optical on-chip interconnect.

By the way, in FIG. 16G, FIG. 17G, and FIG. 18G described above, while steps before the interconnect step and cross sectional structures are shown, when an optical integrated circuit is formed, a desired interconnect process may be applied subsequently.

Further, when this is hybridized with an electronic circuit, several of the steps described above can be performed simultaneously with a step of forming transistors. When an optical device is prepared through a usual silicon process, the device can be easily hybridized with an electronic device.

Particularly, since the germanium laser diode according to the invention can oscillate at about 1500 nm with less transmission loss of optical fiber, it has been found that a laser of high reliability and at low cost can be provided while utilizing existent infrastructures for optical communication as they are.

### LIST OF REFERENCES SIGNS

1 . . . silicon substrate
2 . . . silicon dioxide
3 . . . GOI (germanium On Insulator)
4 . . . silicon dioxide
5 . . . p-type diffusion electrode
6 . . . silicon dioxide
7 . . . single crystal germanium
8 . . . n-type diffusion layer electrode
9 . . . silicon dioxide
10 . . . TiN electrode
11 . . . Al electrode
101 . . . amorphous silicon DBR mirror
102 . . . silicon dioxide
201 . . . silicon nitride
301, 401 . . . silicon substrate
302, 402 . . . silicon dioxide
303, 403 . . . GOI (Germanium On Insulator)
308 . . . silicon dioxide
309, 411 . . . TiN electrode
310, 412 . . . Al electrode
405 . . . silicon nitride.
406 . . . germanium dioxide
407, 410 . . . silicon dioxide

1. A light-emitting element comprising:
a light-emitting portion including a single crystal germanium layer disposed on a silicon dioxide film over a silicon substrate;
a first electrode having a first conduction type disposed adjacent to one end of the single crystal germanium layer; and
a second electrode having a conduction type opposite to the first conduction type, disposed adjacent to the other end of the single crystal germanium;
wherein light is generated from the light-emitting portion by supplying a current between the first electrode and the second electrode.

2. The light-emitting device according to claim 1,
wherein the first electrode, the second electrode, and the light-emitting portion are arranged in parallel to a main surface of the silicon substrate, and disposed adjacent to the silicon dioxide.

3. The light-emitting device according to claim 2,
wherein the first electrode includes germanium doped with an impurity to an n-type or p-type state, and
the second electrode includes germanium doped with an impurity of a conduction type opposite to that of the first electrode.

4. The light-emitting device according to claim 2,
wherein a dielectric layer including a first dielectric material having a shape of a fine line of a size that operates as an optical resonator is disposed, by way of a dielectric material adjacent to the light emitting portion.

5. The light-emitting device according to claim 4,
wherein the first dielectric material includes a material of one of single crystal silicon, polycrystal silicon, amorphous silicon, silicon dioxide, silicon nitride, SiON, Al₂O₃, Ta₂O₅, HfO₂, and TiO₂, or a combination thereof.

6. The light-emitting device according to claim 5,
wherein a dielectric material including a second dielectric material fabricated into small pieces is disposed on both ends of the fine line portion of the first dielectric material each by one or in plurality.

7. The light-emitting device according to claim 2, having a plurality of second dielectric material in small pieces disposed periodically by way of a dielectric material adjacent to the light emitting portion.

8. A light-emitting device according to claim 2,
wherein the light-emitting portion has a ridged structure.

9. The light-emitting device according to claim 8,
wherein a dielectric material including a second dielectric material fabricated into small pieces is disposed each by one or in plurality on both ends of the light-emitting portion.

10. The light-emitting device according to claim 8, having a plurality of second dielectric materials in small pieces disposed periodically by way of a dielectric material adjacent to the light emitting portion.

11. The light-emitting device according to claim 1,
wherein the first electrode is disposed adjacent to the silicon dioxide, the light-emitting portion is disposed over the first electrode, and the second electrode is disposed over the light-emitting portion.

12. The light-emitting device according to claim 11,
wherein the first electrode includes germanium doped with an impurity to a p-type state, and
the second electrode includes silicon or silicon germanium doped with an impurity to an n-type state.

13. The light-emitting device according to claim 11,
wherein the light-emitting portion has a shape of a fine line of a size that operates as an optical resonator.

14. The light-emitting device according to claim 13,
wherein a dielectric material including a second dielectric material fabricated into small pieces is disposed on both ends of the fine line portion of the first dielectric material each by one or in plurality.

15. The light-emitting device according to claim 14,
wherein the second dielectric material includes a material of one of single crystal silicon, polycrystal silicon, amorphous silicon, silicon dioxide, silicon nitride, SiON, Al₂O₃, Ta₂O₅, HfO₂, and TiO₂, or a combination thereof.

16. The light-emitting device according to claim 11, having a plurality of light-emitting portions in a shape of small pieces in which respective light-emitting portions are arranged in parallel with each other over the silicon dioxide.

17. The light-emitting device according to claim 1,
wherein a silicon nitride film is disposed over the light-emitting device.
